(19) United States
(12) Patent Application Publication
(10) Pub. No.: US 2025/0331114 A1
(43) Pub. Date: Oct. 23, 2025

(54) COVER MEMBER AND METHOD FOR MANUFACTURING COVER MEMBER

(71) Applicant: AGC Inc., Tokyo (JP)

(72) Inventors: Yuji IMOTO, Tokyo (JP); Yusuke FUJIWARA, Tokyo (JP)

(73) Assignee: AGC Inc., Tokyo (JP)

(21) Appl. No.: 19/252,706

(22) Filed: Jun. 27, 2025

Related U.S. Application Data
(63) Continuation of application No. PCT/JP2023/046263, filed on Dec. 22, 2023.

(30) Foreign Application Priority Data
Dec. 27, 2022 (JP) 2022-210630

(51) Int. Cl. H05K 5/03

(52) U.S. Cl. CPC H05K 5/03

(57) ABSTRACT

The present invention relates to a cover member for a display, including: a first glass; a first resin that is a thermoplastic resin or a thermoplastic elastomer; and a second resin that is provided between a side surface of the first glass and a first side surface of the first resin and configured to bond the first glass and the first resin, in which the second resin is a resin different from the first resin and has a loss modulus G″ of 10⁶ Pa or more at 35° C.

### CROSS-REFERENCE TO RELATED APPLICATIONS

This is a continuation of International Application No. PCT/JP2023/046263 filed on Dec. 22, 2023, and claims priority from Japanese Patent Application No. 2022-210630 filed on Dec. 27, 2022, the entire content of which is incorporated herein by reference.

### TECHNICAL FIELD

The present invention relates to a cover member and a method for producing a cover member.

### BACKGROUND ART

There is a case where it is required to impart flexibility to a cover member disposed to protect a protection target such as a display. For example, Patent Literature 1 describes a cover member that can be bent with a UV (ultraviolet) curable resin as a starting point by providing the UV curable resin between glasses arranged in a lateral direction.
Patent Literature 1: US2021/0107251

### SUMMARY OF INVENTION

However, in the case where the UV curable resin is provided between the glasses as in Patent Literature 1, it is necessary to fill an entire region, to be imparted with flexibility, with the UV curable resin, and it takes time and effort in a step of filling with an uncured resin and a step of curing the filled resin during production. In addition, in a cover member in which a glass and a resin are bonded to each other, a bonded portion may be peeled off due to repeated bending. Therefore, it is required to prevent breakage and peeling-off of the bonded portion due to bending while simplifying a production process.

An object of the present invention is to provide a cover member and a method for producing a cover member capable of preventing breakage and peeling-off of a bonded portion due to bending.

A cover member according to the present disclosure is a cover member of a display, including: a first glass; a first resin that is a thermoplastic resin or a thermoplastic elastomer; and a second resin that is provided between a side surface of the first glass and a first side surface of the first resin and configured to bond the first glass and the first resin, in which the second resin is a resin different from the first resin and has a loss modulus G″ of 10⁶ Pa or more at 35° C.

A cover member according to the present disclosure includes: a first glass; a first resin; and a second resin provided between a side surface of the first glass and a side surface of the first resin and configured to bond the first glass and the first resin, in which after a bending durability test in which bending is performed 200,000 times at a curvature radius of bending of 20 mm, the first resin and the second resin have no broken portion, and a bonded portion between the first resin and the second resin and a bonded portion between the first glass and the second resin are not peeled off.

A cover member according to the present disclosure is a cover member for a display, including: a first glass having a recessed portion in a part of a main surface; a first resin that is a thermoplastic resin or a thermoplastic elastomer and provided in the recessed portion; a second resin that is provided in the recessed portion and between a side surface of the recessed portion and a first side surface of the first resin and configured to bond the first glass and the first resin; and a third resin that is provided between a bottom surface of the recessed portion and a main surface of the first resin and configured to bond the bottom surface of the recessed portion and the main surface of the first resin, in which the second resin is a resin different from the first resin and has a loss modulus G″ of 10⁶ Pa or more at 35° C.

A method for producing a cover member according to the present disclosure includes: a step of applying a curable resin between a side surface of a first glass and a first side surface of a plate-shaped first resin that is a thermoplastic resin or a thermoplastic elastomer; and a step of curing the curable resin to form a second resin having a loss modulus G″ of 10⁶ Pa or more at 35° C., thereby bonding the first glass and the first resin with the second resin.

According to the present invention, it is possible to prevent breakage and damage of a bonded portion due to bending.

### BRIEF DESCRIPTION OF DRAWINGS

FIG. 1 is a cross-sectional view illustrating a display device according to the present embodiment.

FIG. 2 is a cross-sectional view illustrating a display device according to the present embodiment.

FIG. 3 is a schematic cross-sectional view of a cover member.

FIG. 4 is a schematic top view of the cover member.

FIG. 5A is a schematic diagram illustrating test conditions in a three-point bending strength test.

FIG. 5B is a schematic diagram illustrating test conditions in a bending durability test.

FIG. 6 is a schematic diagram illustrating a method for producing a cover member according to the present embodiment.

FIG. 7 is a schematic diagram illustrating another example of the cover member.

FIG. 8 is a schematic diagram illustrating still another example of the cover member.

FIG. 9 is a schematic diagram illustrating yet another example of the cover member.

FIG. 10 is a schematic diagram illustrating further another example of the cover member.

FIG. 11 is a schematic diagram illustrating still further another example of the cover member.

FIG. 12 is a schematic diagram illustrating yet further another example of the cover member.

### DESCRIPTION OF EMBODIMENTS

Preferred embodiments of the present invention are described below in detail with reference to the accompanying drawings. Note that, the present invention is not limited to the embodiment and, in the case where there are a plurality of embodiments, also includes a combination of the embodiments. In addition, numerical values include rounding ranges.

Note that, in the present embodiment, unless otherwise specified, “peeling-off” refers to at least one of interfacial breakage of a bonded portion between bonded members and cohesive breakage of a member corresponding to an adhesive among the bonded members. In addition, the “breakage” refers to a crack in a bent portion when a member is bent, unless otherwise specified. In addition, “cloudiness” means that the resin is white and cloudy due to fatigue, unless otherwise specified. In addition, the “damage” refers to a state where it is difficult to use as a cover member due to peeling, breakage, cloudiness, and the like, unless otherwise specified.

### (Display Device)

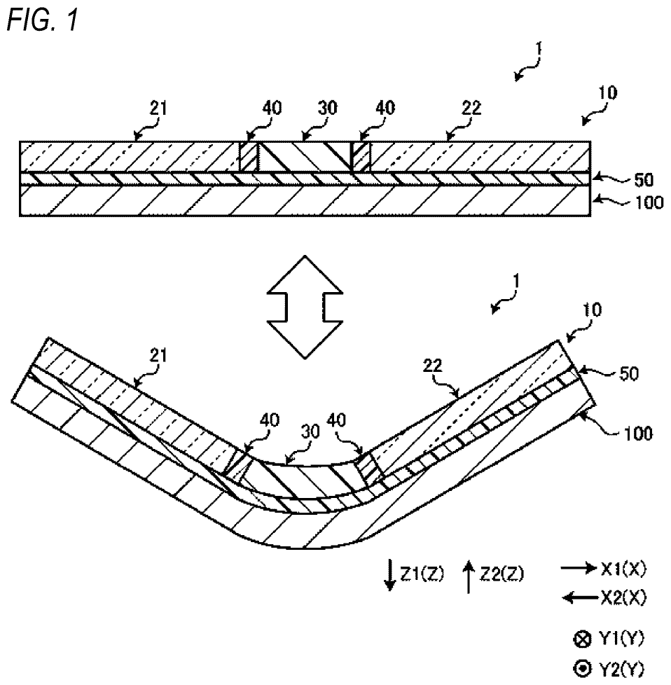

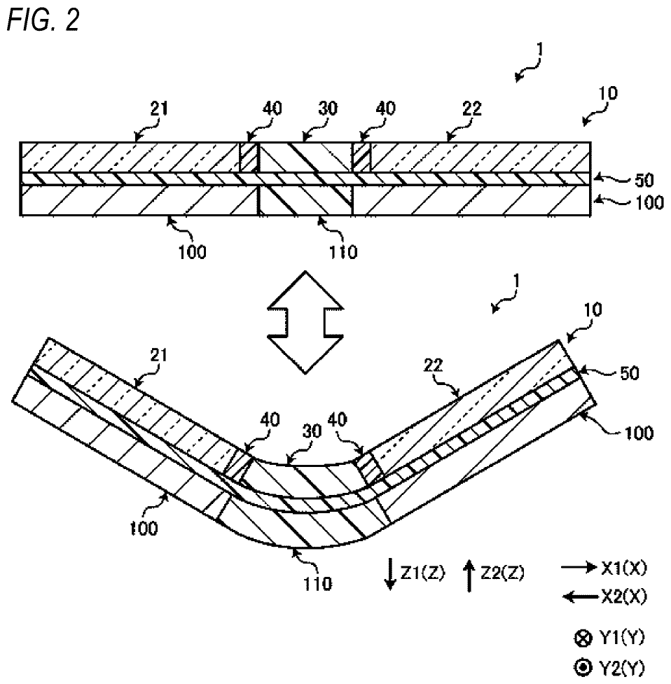

FIGS. 1 and 2 are cross-sectional views illustrating a display device according to the present embodiment. A display device 1 according to the present embodiment is a display device to be provided in a vehicle, and is provided, for example, on a front side of a driver seat and a passenger seat in the vehicle. However, the display device 1 may be used not only for a vehicle application but also for any application, and may be provided at any position.

Hereinafter, a thickness direction (stacking direction) of the display device 1 (cover member 10) is referred to as a Z direction, one direction perpendicular to the Z direction (a left-right direction in the example in FIG. 1) is referred to as an X direction, and a direction perpendicular to the Z direction and the X direction (a direction perpendicular to the paper surface in the example in FIG. 1) is referred to as a Y direction. In addition, one direction along the X direction (right direction in the example in FIG. 1) is defined as a direction X1, and the other direction along the X direction (left direction in the example in FIG. 1) is defined as a direction X2. One direction along the Y direction (direction toward the back of the paper in the example in FIG. 1) is defined as a direction Y1, and the other direction along the Y direction (direction toward the front of the paper in the example in FIG. 1) is defined as a direction Y2. One direction along the Z direction (direction from a display surface toward a back surface of the display device 1) is defined as a direction Z1, and the other direction along the Z direction (direction from the back surface toward the display surface of the display device 1) is defined as a direction Z2.

Note that, the Z direction here is a direction perpendicular to a main surface 10A in a state where the cover member 10 of the display device 1 is not bent and is flat as to be described later (a state where the main surface 10A is fixed in contact with a flat surface).

As illustrated in FIG. 1, the display device 1 is bendable. The display device 1 can be bent such that the direction Z2 side is recessed with the Y direction as a bending axis. However, the bending axis and the recess direction are not limited thereto, and may be any. For example, the bending axis may be any direction orthogonal to the Z direction (for example, the X direction), or bending can be performed such that the direction Z1 side is recessed.

Note that, it can be said that the bending axis is a central axis of a curvature circle when the display device 1 (cover member 10) is bent. In addition, “bendable” means that bending and expansion can be performed at a predetermined bending axis, in other words, bending can be performed at a predetermined bending axis by elastic deformation.

The display device 1 includes the cover member 10, a connection layer 50, and a display panel 100. In the display device 1, the cover member 10, the connection layer 50, and the display panel 100 are stacked in this order toward the direction Z1. The cover member 10 is provided on a surface (display surface) of the display panel 100 on the direction Z2 side and protects the display surface of the display panel 100. However, the cover member 10 is not limited to being used as a cover material of the display panel 100. A target to be protected may be any object and the cover member 10 may be used for any application. A configuration of the cover member 10 is to be described later.

The connection layer 50 is a layer that is provided between the cover member 10 and the display panel 100 in the Z direction and that adheres a main surface of the cover member 10 on the direction Z1 side and a main surface (display surface) of the display panel 100 on the direction Z2 side. The connection layer 50 is bendable. The connection layer 50 may be formed of any bendable member that adheres the cover member 10 and the display panel 100. For example, the connection layer 50 may be an optical clear adhesive (OCA) or an optical clear resin (OCR). However, the connection layer 50 is not an essential component, and may not be provided in the display device 1.

### (Display Panel)

The display panel 100 is a display that displays an image. The display panel 100 may be any display capable of displaying an image, and examples thereof include a liquid crystal panel, an organic EL panel, a PDP, and an electronic ink type panel, and may include a touch panel.

The display panel 100 may be bendable as illustrated in FIG. 1, or may not be bendable as illustrated in FIG. 2. In the example in FIG. 2, the display panel 100 is not provided at a bent portion (a portion of a first resin 30, to be described later, on the direction Z1 side), but is provided at a position away from the bent portion. Specifically, a bendable panel connection layer 110 is provided at the bent portion (the portion of the first resin 30, to be described later, on the direction Z1 side), and the display panel 100 is provided on the panel connection layer 110 on each of the direction X1 side and the direction X2 side. In this case, each display panel 100 is bonded to the panel connection layer 110. The panel connection layer 110 may be any bendable member, and may be, for example, the same material as the first resin 30 to be described later.

Note that, examples of the bendable display panel 100 include an organic EL panel, and examples of the unbendable display panel 100 include a liquid crystal panel.

### (Cover Member)

A cover member according to the present disclosure is a cover member for a display, including: a first glass; a first resin that is a thermoplastic resin or a thermoplastic elastomer; and a second resin that is provided between a side surface of the first glass and a first side surface of the first resin and configured to bond the first glass and the first resin, in which the second resin is a resin different from the first resin and has a loss modulus G″ of 10⁶ Pa or more at 35° C.

The cover member according to the present disclosure may further include a second glass, and the second resin may also be provided between a second side surface of the first resin and a side surface of the second glass to bond the first resin and the second glass.

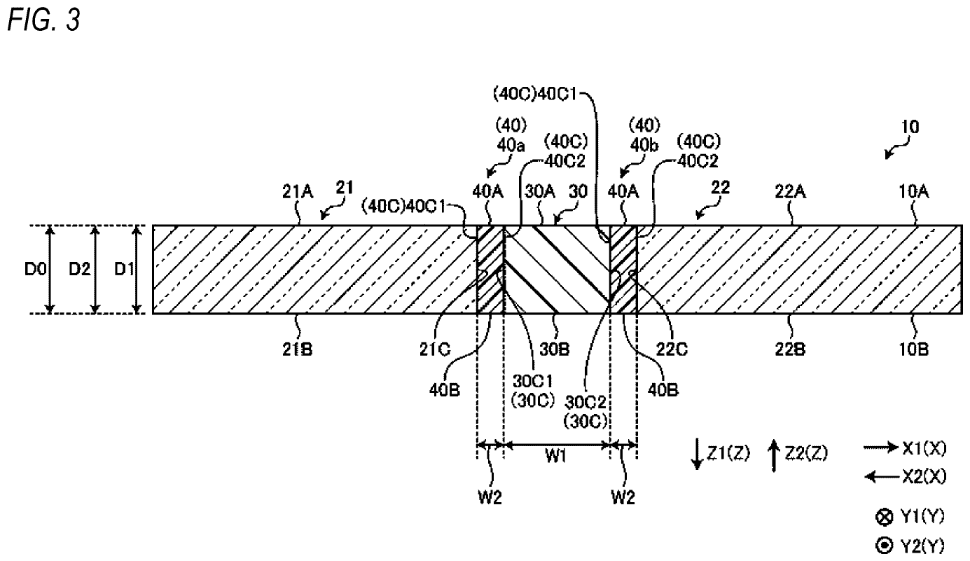

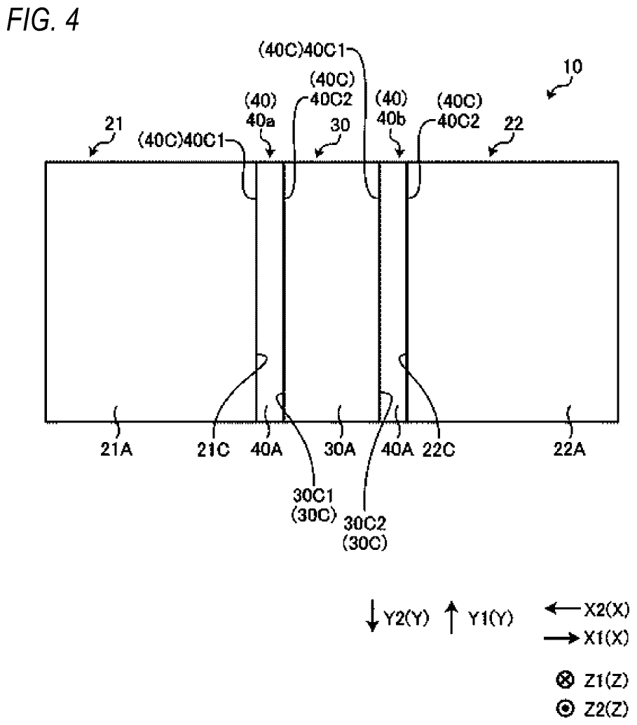

FIG. 3 is a schematic cross-sectional view of the cover member, and FIG. 4 is a schematic top view of the cover member. The cover member 10 is a plate-shaped member having the main surface 10A that is a main surface on the direction Z2 side and a main surface 10B that is a main surface on the direction Z1 side.

The cover member 10 is bendable. In the present embodiment, the cover member 10 is flat when the cover member 10 is placed on a flat surface with the main surface 10A facing downward. For example, in the case of being mounted on the display device 1 or the like, the cover member 10 is in a bent state due to elastic deformation, as illustrated in FIGS. 1 and 2. Here, the state where the cover member 10 is allowed to be placed flat refers to a state where substantially the entire main surface 10A is in contact with the flat surface only by its own weight, and can also be said to be a state where no load is received from the outside and the cover member 10 is not elastically deformed by an external load. Note that, substantially the entire main surface 10A may mean that the entire main surface 10A is a flat surface, but is not limited to this, and may refer to, for example, a region having 95% or more of the area of the entire main surface 10A. In addition, the cover member 10 may be a curved surface in a state where the cover member 10 is placed on a flat surface. The curved surface is formed, for example, by heating and shaping a first glass 21 and a second glass 22.

Hereinafter, it is assumed that the cover member 10 is placed on a flat surface unless otherwise specified.

As illustrated in FIGS. 3 and 4, the cover member 10 includes the first glass 21, the second glass 22, the first resin 30, and a second resin 40. The first glass 21, the second glass 22, the first resin 30, and the second resin 40 are arranged in a direction orthogonal to the Z direction, and are arranged in the X direction in the example of the present embodiment. Specifically, in the present embodiment, the first glass 21, a second resin 40a as the second resin 40, the first resin 30, a second resin 40b as the second resin 40, and the second glass 22 are arranged in this order toward the direction X1.

The main surface 10A of the cover member 10 on the direction Z2 side includes a main surface 21A of the first glass 21 on the direction Z2 side, a main surface 22A of the second glass 22 on the direction Z2 side, a main surface 30A of the first resin 30 on the direction Z2 side, and a main surface 40A of the second resin 40 on the direction Z2 side. Similarly, the main surface 10B of the cover member 10 on the direction Z1 side includes a main surface 21B of the first glass 21 on the direction Z1 side, a main surface 22B of the second glass 22 on the direction Z1 side, a main surface 30B of the first resin 30 on the direction Z1 side, and a main surface 40B of the second resin 40 on the direction Z1 side.

### (First Glass)

The first glass 21 is a plate-shaped member made of glass. The first glass 21 has the main surface 21A that is a main surface on the direction Z2 side, the main surface 21B (main surface opposite to the main surface 21A) that is a main surface on the direction Z1 side, and a side surface 21C that is a surface extending in a direction intersecting the Z direction. In the example of the present embodiment, the side surface 21C can also be said to be an end surface connecting the main surface 21A and the main surface 21B. The side surface 21C of the first glass 21 on the first resin 30 side (the direction X1 side in the present example) is bonded to the second resin 40a.

In the example of the present embodiment, the first glass 21 has a rectangular shape when viewed from the Z direction. However, the shape of the first glass 21 may be any.

A thickness D0 of the first glass 21 is, for example, 0.4 mm or more, preferably 0.7 mm or more, more preferably 0.8 mm or more, and still more preferably 1.0 mm or more. In the case where the thickness D0 is within this range, it is possible to prevent a decrease in bondability with the second resin 40 due to the first glass 21 being too thin. In addition, the thickness D0 of the first glass 21 is preferably 0.7 mm or more and 5.0 mm or less, more preferably 0.8 mm or more and 3.0 mm or less, and still more preferably 1.0 mm or more and 2.0 mm or less. In the case where the upper limit of the thickness D0 is within this range, a bonding area between the first glass 21 and the second resin 40 can be prevented from being excessively large, and a production process can be simplified. In addition, in the case where the upper limit of the thickness DO is within this range, an excessive increase in stress generated when the second resin 40 is bent can be reduced, and damage can be prevented.

Note that, the thickness D0 refers to a distance in the Z direction from the main surface 21A to the main surface 21B of the first glass 21.

A refractive index n_{d} of the first glass 21 is preferably 1.47 or more and 1.55 or less, and more preferably 1.49 or more and 1.53 or less. In the case where the refractive index n_{d} is within this range, light from the display device can be appropriately visually recognized by a user.

Note that, the refractive index n_{d} refers to a refractive index at a d-line of helium (wavelength: 587.6 nm). The refractive index n_{d} can be measured by using a V block method.

A Young's modulus of the first glass 21 is preferably 60 GPa or more, and more preferably 70 GPa or more. In addition, the Young's modulus of the first glass 21 is preferably 60 GPa or more and 95 GPa or less, and more preferably 70 GPa or more and 90 GPa or less. In the case where the Young's modulus of the first glass 21 is within this range, damage can be appropriately prevented. The Young's modulus of each member including the first glass 21 may be obtained by a tensile test (JIS K7161, JIS K7113).

The first glass 21 is preferably a strengthened glass such as a chemically strengthened glass.

In the case where the first glass 21 is a chemically strengthened glass, a thickness (DOL) of a compressive stress layer of the first glass 21 is, for example, preferably 5 μm or more, more preferably 10 μm or more, and still more preferably 15 μm or more. In addition, the thickness (DOL) of the compressive stress layer is, for example, preferably 180 μm or less, and more preferably 50 μm or less.

A surface compressive stress (CS) of the compressive stress layer is preferably 500 MPa or more, more preferably 650 MPa or more, and still more preferably 750 MPa or more. An upper limit is not particularly limited, and the CS is preferably 1,200 MPa or less, for example.

As a method for obtaining a chemically strengthened glass by subjecting a glass to a chemical strengthening treatment, a known method may be used. Examples of a molten salt used for the chemical strengthening treatment include alkali nitrate salts, alkali sulfate salts, and alkali chloride salts, such as potassium nitrate, sodium nitrate, potassium sulfate, and sodium sulfate. These molten salts are not limited to being used alone, a plurality of types of molten salts may be used in combination, and other salts may be mixed to adjust chemically strengthened properties. Accordingly, in a surface layer of the first glass 21, alkali ions (Li ions or Na ions) are ion-exchanged (substituted) with other alkali ions (Na ions or K ions) having a larger ion radius in the molten salt, followed by cooling to around normal temperature. With this ion exchange, a layer (compressive stress layer), in which a compressive stress is generated due to a high density, is formed on the surface layer of the first glass 21. Thus, the first glass 21 can be strengthened. Treatment conditions such as a temperature of the molten salt and an immersion time may be set such that the compressive stress value (CS) of the compressive stress layer and the thickness (DOL) of the compressive stress layer have desired values.

The first glass 21 subjected to the chemical strengthening treatment may be further subjected to an acid treatment and an alkali treatment.

The acid treatment is a treatment in which the first glass 21 subjected to the chemical strengthening treatment is immersed in an acid solution. Accordingly, Na and/or K on the surface of the first glass 21 subjected to the chemical strengthening treatment is substituted with H. That is, a surface layer of the compressive stress layer in the first glass 21 subjected to the chemical strengthening treatment is altered to a low-density layer having a low density.

The alkali treatment is a treatment in which the first glass 21 subjected to the acid treatment is immersed in a basic solution. Accordingly, a part or all of the low-density layer formed by the acid treatment is removed. Thus, cracks or latent scratches present on the surface of the first glass 21 can be removed together with the low-density layer.

A material of the first glass 21 may be any material, and examples thereof include a soda lime glass and an aluminosilicate glass (SiO₂—Al₂O₃—Na₂O-based glass or SiO₂—Al₂O₃—Li₂O—Na₂O-based glass). Among them, an aluminosilicate glass is preferred from the viewpoint of strength.

Examples of the material of the first glass 21 include: a glass material containing, in mol % in terms of oxides, 50% or more and 80% or less of SiO₂, 1% or more and 20% or less of Al₂O₃, 6% or more and 20% or less of Na₂O, 0% or more and 11% or less of K₂O, 0% or more and 15% or less of MgO, 0% or more and 6% or less of CaO, and 0% or more and 5% or less of ZrO₂; and a glass material containing, in mol % in terms of oxides, 50% or more and 80% or less of SiO₂, 2% or more and 25% or less of Al₂O₃, 0.1% or more and 20% or less of Li₂O, 0.1% or more and 18% or less of Na₂O, 0% or more and 10% or less of K₂O, 0% or more and 15% or less of MgO, 0% or more and 5% or less of CaO, 0% or more and 5% or less of P₂O₅, 0% or more and 5% or less of B₂O₃, 0% or more and 5% or less of Y₂O₃, and 0% or more and 5% or less of ZrO₂.

In addition, as the material of the first glass 21, a glass for chemical strengthening, which is based on an aluminosilicate glass, (for example, “Dragontrail (registered trademark)” manufactured by AGC Inc.) can be also suitably used.

### (Second Glass)

The second glass 22 is a plate-shaped member made of a glass. The second glass 22 has the main surface 22A that is a main surface on the direction Z2 side, the main surface 22B (main surface opposite to the main surface 22A) that is a main surface on the direction Z1 side, and a side surface 22C that is a surface extending in the direction intersecting the Z direction. The example of the present embodiment, the side surface 22C can also be said to be an end surface connecting the main surface 22A and the main surface 22B. The side surface 22C of the second glass 22 on the first resin 30 side (the direction X2 side in the present example) is bonded to the second resin 40b.

Since properties of the second glass 22 are the same as the properties of the first glass 21 described above, the description thereof is omitted. That is, for example, a thickness, a refractive index, a Young's modulus, and a composition of the second glass 22 may be the same as those of the first glass 21. Similar to the first glass 21, the second glass 22 may be a strengthened glass such as a chemically strengthened glass, and the properties and the chemical strengthening method thereof may be the same as those of the first glass 21.

### (First Resin)

The first resin 30 is a member constituting a bent portion of the cover member 10. The first resin 30 has the main surface 30A that is a main surface on the direction Z2 side, the main surface 30B (main surface opposite to the main surface 30A) that is a main surface on the direction Z1 side, and a side surface 30C that is a surface extending in the direction intersecting the Z direction. It can be said that the side surface 30C is an end surface connecting the main surface 30A and the main surface 30B. In the first resin 30, a side surface 30C1 (first side surface) that is the side surface 30C on the first glass 21 side (the direction X2 side in the present example) is bonded to the second resin 40a, and a side surface 30C2 (second side surface) that is the side surface 30C on the second glass 22 side (the direction X1 side in the present example) is bonded to the second resin 40b.

That is, as illustrated in FIG. 4, the first resin 30 is provided to be positioned between the first glass 21 and the second glass 22 in the X direction and to extend in the Y direction. Therefore, in the example of the present embodiment, the cover member 10 can be bent with the first resin 30 as a starting point of bending and the Y direction as a bending axis.

The first resin 30 is preferably a member made of a thermoplastic resin or a thermoplastic elastomer. The first resin 30 may be made of any thermoplastic resin or any thermoplastic elastomer. A main component thereof is preferably at least one or more selected from a polyester, an acrylic resin, a polyethylene (PE), and a polycarbonate (PC), the main component is more preferably a polyester, and the main component is still more preferably a polyethylene terephthalate (PET). Examples of the acrylic resin include polymethyl methacrylate (PMMA). The main component here means that the content with respect to the entire first resin 30 is 50 mass % or more and 100 mass % or less, preferably 70 mass % or more and 100 mass % or less, more preferably 90 mass % or more and 100 mass % or less, and still more preferably 100 mass %.

By forming the first resin 30 with such a member, the production process can be simplified. That is, for example, by using a thermoplastic member as the first resin 30, it is possible to produce the cover member 10 by bonding the sheet-shaped first resin 30 sufficiently cured at normal temperature with the second resin 40. Therefore, a step of filling with an uncured resin and a step of curing the filled resin are unnecessary for the first resin 30, and the production process can be simplified. Further, in a cover member for a vehicle application having a large area, it is necessary to enlarge the bent portion, and it is particularly preferred to produce the bent portion with the first resin 30 in advance since the filling step and the curing step can be omitted in the large portion. By forming the first resin 30 with such a member, breakage and cloudiness of the bent portion due to repeated bending can be prevented.

The first resin 30 preferably contains a member having a tensile elastic modulus of 2,000 MPa or more and 4,000 MPa or less as a main component, more preferably contains a member having a tensile elastic modulus of 2,100 MPa or more and 3,900 MPa or less as a main component, and still more preferably contains a member having a tensile elastic modulus of 2,200 MPa or more and 3,800 MPa or less as a main component. By using a member having a tensile elastic modulus within this range, damage of the bent portion due to repeated bending can be more suitably prevented. Note that, the tensile elastic modulus can be measured based on ISO 527-1 and ISO 527-2.

A glass transition temperature Tg of the first resin 30 is preferably 60° C. or higher and 200° C. or lower, more preferably 65° C. or higher and 195° C. or lower, and still more preferably 70° C. or higher and 190° C. or lower. By using the first resin 30 having the glass transition temperature Tg within this range, the cover member 10 can be produced by using the sufficiently cured first resin 30, and thus the production process can be simplified.

In the case where the display panel is installed under the first resin 30 as illustrated in FIG. 1 and in the case where the display panel is not installed under the first resin 30 as illustrated in FIG. 2, the first resin 30 is preferably transparent to visible light when it is desired to increase the sense of unity of the cover member. For example, the first resin 30 preferably has an external transmittance of 70% or more for light having a wavelength of 550 nm.

Note that, the external transmittance can be measured by using a general spectrophotometer. An intensity 10 of a luminous flux is measured in a state where a sample is not placed, then the sample is placed on the measurement luminous flux, and an intensity IT of the luminous flux transmitted through the sample is measured. Using these, an external transmittance T can be measured according to the following equation (1).

$$T = 100 \cdot IT / I 0 \qquad ( 1 )$$

At this time, the refractive index n_{d} of the first resin 30 is preferably closer to the refractive index n_{d} of the first glass 21, and is preferably greater than the refractive index n_{d} of the first glass 21. The refractive index n_{d} of the first resin 30 is preferably 1.30 or more and 1.70 or less, and more preferably 1.40 or more and 1.60 or less. In the case where the refractive index n_{d} is within this range, the light from the display device can be appropriately visually recognized by the user.

A difference between the refractive index n_{d} of the first resin 30 and the refractive index n_{d} of the first glass 21 is preferably 0.001 or more and 0.15 or less, more preferably 0.003 or more and 0.1 or less, and still more preferably 0.005 or more and 0.05 or less.

On the other hand, in the case where the display panel 100 is not installed under the first resin 30 as illustrated in FIG. 2, since the first resin 30 is colored, it is possible to provide an effect of concealing a wiring or the like of the display panel 100 from the user. In this case, the first resin 30 is black, for example, and may have a pattern such as a wood grain pattern or a marble pattern.

A thickness D1 of the first resin 30 is preferably 0.7 mm or more, more preferably 0.8 mm or more, and still more preferably 1.0 mm or more. In the case where the thickness D1 is within this range, it is possible to prevent a decrease in bondability with the second resin 40 due to the first resin 30 being too thin. In addition, the thickness D1 of the first resin 30 is preferably 0.7 mm or more and 5.0 mm or less, more preferably 0.8 mm or more and 3.0 mm or less, and still more preferably 1.0 mm or more and 2.0 mm or less. In the case where the upper limit of the thickness D1 is within this range, a bonding area can be prevented from being excessively large, and the production process can be simplified.

Note that, the thickness D1 refers to a distance in the first resin 30 in the Z direction from the main surface 30A on the direction Z2 side to the main surface 30B on the direction Z1 side.

A difference between the thickness D1 of the first resin 30 and the thickness DO of the first glass 21 is preferably 100 μm or less, more preferably 80 μm or less, and still more preferably 60 μm or less. With such a small difference in thickness, a step between the first resin 30 and the first glass 21 can be reduced. Note that, in the case of providing a third glass 23 on the main surface 30A of the first resin 30 as illustrated in FIG. 8 to be described later, a total value of the thickness of the first resin 30 and the thickness of the third glass 23 may be treated as the thickness D1 of the first resin 30.

A width W1 of the first resin 30 is preferably 2.0 cm or more, more preferably 3.0 cm or more and 15 cm or less, and still more preferably 4.0 cm or more and 10 cm or less. In the case where the width W1 is 2.0 cm or more, the bent portion can be sufficiently enlarged, and the cover member 10 can be appropriately bent. In addition, by forming such a relatively large bent portion with the first resin 30, a step of filling with an uncured resin is unnecessary, which is also preferred from the viewpoint of simplifying the production process. In addition, in the case where the width W1 is 10 cm or less, it is possible to prevent the bent portion from being too large and to improve visibility of the image.

Note that, the width W1 refers to a distance in a direction in which the first resin 30, the second resin 40, and the first glass 21 are arranged, and refers to a distance in the X direction from the side surface 30C1 to the side surface 30C2.

### (Second Resin)

The second resin 40 is a member that connects the first glass 21 (or the second glass 22) and the first resin 30. The second resin 40 has the main surface 40A that is a main surface on the direction Z2 side, the main surface 40B (main surface opposite to the main surface 40A) that is a main surface on the direction Z1 side, and a side surface 40C that is a surface extending in the direction intersecting the Z direction. It can be said that the side surface 40C is an end surface connecting the main surface 40A and the main surface 40B.

In the present embodiment, the second resin 40a connecting the first glass 21 and the first resin 30 and the second resin 40b connecting the second glass 22 and the first resin 30 are provided as the second resin 40. The second resin 40a is provided between the first glass 21 and the first resin 30 in the X direction, and bonds the side surface 21C of the first glass 21 on the direction X1 side and the side surface 30C1 of the first resin 30 on the direction X2 side. That is, in the second resin 40a, a side surface 40C1 on the first glass 21 side (the direction X2 side in the present example) is bonded to the side surface 21C of the first glass 21 on the direction X1 side, and a side surface 40C2 on the first resin 30 side (the direction X1 side in the present example) is bonded to the side surface 30C1 of the first resin 30. Similarly, the second resin 40b is provided between the first resin 30 and the second glass 22 in the X direction, and bonds the side surface 30C2 of the first resin 30 on the direction X1 side and the side surface 22C of the second glass 22 on the direction X2 side. That is, in the second resin 40b, the side surface 40C1 on the first resin 30 side (the direction X2 side in the present example) is bonded to the side surface 30C2 of the first resin 30, and the side surface 40C2 on the second glass 22 side (the direction X1 side in the present example) is bonded to the side surface 22C of the second glass 22 on the direction X2 side.

Hereinafter, properties of the second resin 40 are described, and unless otherwise specified, refer to the properties of both the second resins 40a and 40b.

The second resin 40 is preferably a resin different from the first resin 30. That is, the second resin 40 preferably has a composition different from that of the first resin 30. A loss modulus G″ of the second resin 40 at normal temperature (35° C.) is preferably 10⁶ Pa or more, more preferably 3.0×10⁶ Pa or more and 2.0×10¹⁵ Pa or less, and still more preferably 4.0×10⁶ Pa or more and 1.0×10¹⁵ Pa or less. In the case where the loss modulus G″ of the second resin 40 is within this range, cohesive breakage of the second resin 40 can be prevented, durability against a tensile force during repeated bending can be improved, the first resin 30 and the first glass 21 (or the second glass 22) are appropriately bonded to each other, and peeling-off at a bonded portion due to bending can be prevented. The bonded portion here refers to a bonded portion between the first resin 30 and the second resin 40 or a bonded portion between the second resin 40 and the first glass 21 (or the second glass 22).

Note that, the loss modulus G″ can be measured, for example, under the following measurement conditions using a dynamic viscoelasticity measurement device (for example, DVA-200 manufactured by IT Instrumentation and Control Co., Ltd.). In the case where repeated bending is performed, a tensile stress is repeatedly generated in the second resin 40 between the first resin 30 and the first glass 21. In the dynamic viscoelasticity measurement, similarly, viscoelasticity properties when a tensile force is periodically applied to the sample can be obtained, and the values of the loss modulus G″, a storage modulus G′, and tan 8 are mainly obtained. In particular, the loss modulus G″ represents a viscous term and means the ease of diffusion of the stress generated by the tensile force to the outside. Therefore, with the loss modulus G″, it is possible to see the ease of cohesive breakage of the second resin 40 itself when repeated bending is performed.

The measurement conditions for the loss modulus G″ may be, for example, as follows. The second resin 40 is cut into a strip shape having a thickness of 1 mm, a long side of 30 mm, and a short side of 2 mm, and a long side end portion is sandwiched between fixing portions of the device. The measurement is performed in a tensile mode at a measurement temperature of 35° C. to 50° C. (1° C. interval) and a measurement frequency of 1 Hz.

The second resin 40 is preferably a resin obtained by curing a curable resin. Here, the curable resin refers to a resin which is in a liquid state having fluidity before curing and is cured and solidified by a predetermined step. That is, it can be said that the second resin 40 is a cured body of a curable resin in a liquid state having fluidity. Examples of the predetermined step here include heating or irradiation with light (for example, ultraviolet rays), and in other words, examples of the curable resin include a thermosetting resin and a photocurable resin (for example, a UV curable resin).

The second resin 40 may be a cured body of any curable resin, and the main component is preferably at least one or more selected from a cured acrylic resin and a cured epoxy resin. Examples of the acrylic resin include an amino resin acrylate, a copolymer acrylate, a polyester acrylate, and an epoxy acrylate. Examples of the epoxy resin include a bisphenol type epoxy resin, an alicyclic epoxy resin, and a glycidyl ether epoxy resin. By forming the second resin 40 with such a member, the first resin 30 and the first glass 21 (or the second glass 22) can be appropriately bonded to each other, and peeling-off at the bonded portion due to bending can be prevented.

Note that, the main component here means that the content with respect to the entire second resin 40 is 50 mass % or more and 100 mass % or less, preferably 70 mass % or more and 100 mass % or less, more preferably 90 mass % or more and 100 mass % or less, and still more preferably 100 mass %.

The second resin 40 preferably contains a member having a tensile elastic modulus of 50 MPa or more and 2,000 MPa or less as a main component, more preferably contains a member having a tensile elastic modulus of 100 MPa or more and 1,900 MPa or less as a main component, and still more preferably contains a member having a tensile elastic modulus of 150 MPa or more and 1,800 MPa or less as a main component. By using a member having a tensile elastic modulus within this range, peeling-off can be appropriately prevented.

Further, the second resin 40 preferably contains a member having an elongation at break of 20% or more as a main component, more preferably contains a member having an elongation at break of 25% or more as a main component, and still more preferably contains a member having an elongation at break of 30% or more as a main component. By using a member having an elongation at break within this range, peeling-off can be appropriately prevented. The elongation at break is a ratio of “a difference between a length of the second resin 40 in a tensile direction at break and a length of the second resin 40 in the tensile direction under no load” to “the length of the second resin 40 in the tensile direction under no load” (difference in length/length under no load) when measuring the tensile elastic modulus.

A glass transition temperature Tg of the second resin 40 is preferably −100° C. or higher and lower than 60° C., more preferably −95° C. or higher and 55° C. or lower, and still more preferably −90° C. or higher and 50° C. or lower. By using the second resin 40 having the glass transition temperature Tg within this range, the first resin 30 and the first glass 21 can be appropriately bonded to each other, and peeling-off due to bending can be prevented.

In the cover member, the first resin preferably has a glass transition temperature Tg of 60° C. or higher and 200° C. or lower, and the second resin preferably has a glass transition temperature Tg of −100° C. or higher and lower than 60° C.

In the case where the display panel is installed under the second resin 40 as illustrated in FIG. 1 and in the case where the display panel is not installed under the second resin 40, the second resin 40 is preferably transparent to visible light in the case where it is desired to increase the sense of unity of the cover member. For example, the second resin 40 preferably has an external transmittance of 70% or more for light having a wavelength of 550 nm.

In the cover member, the first resin and the second resin are preferably transparent to visible light.

A refractive index n_{d} of the second resin 40 is preferably close to the refractive index n_{d} of the first glass 21, and is preferably greater than the refractive index n_{d} of the first glass 21. Further, the refractive index n_{d} of the second resin 40 is preferably a value between the refractive index n_{d} of the first glass 21 and the refractive index n_{d} of the first resin 30. In the case where the refractive index n_{d} of the second resin 40 is an intermediate value between the refractive index of the first glass 21 and the refractive index n_{d} of the first resin 30, the refractive index continuously changes, and the bonded portion can be less likely to be visually recognized. The refractive index n_{d} of the second resin 40 is preferably 1.30 or more and 1.70 or less, and more preferably 1.40 or more and 1.60 or less. In the case where the refractive index n_{d} is within this range, the light from the display device can be appropriately visually recognized by the user.

On the other hand, in the case where the display panel 100 is not installed under the second resin 40, when the second resin 40 is colored, it is possible to provide the effect of concealing the wiring or the like of the display panel 100 from the user. In this case, the second resin 40 is black, for example, and may have a pattern such as a wood grain pattern or a marble pattern.

A thickness D2 of the second resin 40 is preferably 0.7 mm or more, more preferably 0.8 mm or more, and still more preferably 1.0 mm or more. In the case where the thickness D2 is within this range, it is possible to prevent a decrease in bondability with the first resin 30 or a glass due to the second resin 40 being too thin. In addition, the thickness D2 of the second resin 40 is preferably 0.7 mm or more and 5.0 mm or less, more preferably 0.8 mm or more and 3.0 mm or less, and still more preferably 1.0 mm or more and 2.0 mm or less. In the case where the upper limit of the thickness D2 is within this range, a bonding area can be prevented from being excessively large, and the production process can be simplified.

Note that, the thickness D2 refers to a distance in the second resin 40 in the Z direction from the main surface 40A on the direction Z2 side to the main surface 40B on the direction Z1 side.

A width W2 of the second resin 40 is preferably 10 μm or more and 3,000 μm or less, more preferably 20 μm or more and 2,000 μm or less, and still more preferably 30 μm or more and 1,000 μm or less. In the case where the width W2 is within this range, it is possible to prevent the size of the bonded portion from being excessively large while appropriately bonding the first resin 30 or the glass.

Note that, the width W2 refers to a distance in a direction in which the first resin 30, the second resin 40, and the first glass 21 are arranged, and refers to a distance in the X direction from the side surface 40C1 to the side surface 40C2.

### (Relationship Between First Resin and Second Resin)

Next, a relationship between the first resin 30 and the second resin 40 is described.

As described above, the first resin 30 and the second resin 40 are different resins. The first resin 30 and the second resin 40 being different resins can be checked by using Fourier transform infrared spectroscopy (FT-IR). Specifically, infrared light transmittances of the first resin 30 and the second resin 40 are measured at each wave number by a microscopic Fourier transform infrared spectrometer FT-IR (for example, Nic-plan/Nicolet 6700 manufactured by Thermo Fisher Scientific Inc.), the horizontal axis is plotted as the wave number and the vertical axis is plotted as the infrared light transmittance or absorbance, and infrared light transmittance waveforms of the first resin 30 and the second resin 40 are acquired. Then, the infrared light transmittance waveform of the first resin 30 and the infrared light transmittance waveform of the second resin 40 are compared with a spectrum library. Accordingly, in the case where combinations of peak positions are different, it can be found that the first resin 30 and the second resin 40 are different resins. Further, in the case where the first resin 30 contains a polyester, the infrared light transmittance waveform thereof preferably has peaks derived from an ester group, at a position at a wave number of 1705 cm⁻¹ or more and 1725 cm⁻¹ or less, a position at a wave number of 1230 cm⁻¹ or more and 1250 cm⁻¹ or less, and a position at a wave number of 1085 cm⁻¹ or more and 1105 cm⁻¹ or less.

In the case where the first resin 30 contains a polycarbonate, the infrared light transmittance waveform thereof preferably has peaks derived from a carbonate group, at a position at a wave number of 1760 cm⁻¹ or more and 1780 cm⁻¹ or less, a position at a wave number of 1200 cm⁻¹ or more and 1220 cm⁻¹ or less, a position at a wave number of 1180 cm⁻¹ or more and 1200 cm⁻¹ or less, and a position at a wave number of 1150 cm⁻¹ or more and 1170 cm⁻¹ or less.

In the case where the first resin 30 contains an acrylic resin, the infrared light transmittance waveform thereof preferably has no peak derived from a methyl group at a position at a wave number of 2800 cm⁻¹ or more and 3000 cm⁻¹ or less, no peak derived from an ester group at a position at a wave number of 1715 cm⁻¹ or more and 1735 cm⁻¹ or less nor a position at a wave number of 1135 cm⁻¹ or more and 1155 cm⁻¹ or less, no peak derived from a benzene ring, and no peak at a position at a wave number of 1800 cm⁻¹ or more and 2500 cm⁻¹ or less.

The infrared light transmittance waveform of the second resin 40 may have a plurality of peaks at the peak positions of the first resin 30, but the combination of the peak positions is preferably different from that of the first resin 30 when viewed in the entire spectrum. The combination of peaks can be determined by a known method or technique. For example, the infrared light transmittance waveform may be compared with the spectrum library, and the positions of the peaks characteristic of the functional groups and the peaks paired due to stretching and bending vibration, disclosed in Hiroshi Horiguchi, N. B. Colthup, Introduction to Infrared and Raman Spectroscopy Third Edition, Infrared Absorbing Review, and the like may be specified. Note that, in the case where the infrared light transmittance waveform of the first resin 30 has a peak at a position (wave number) not included in the infrared light transmittance waveform of the second resin 40 or in the case where the infrared light transmittance waveform of the second resin 40 has a peak at a position (wave number) not included in the infrared light transmittance waveform of the first resin 30, it can be said that the combination of peak positions is different between the infrared light transmittance waveform of the first resin 30 and the infrared light transmittance waveform of the second resin 40.

Note that, the FT-IR measurement conditions may be measured by a transmission method or an ATR method. In the transmission method, a sample is irradiated with infrared light, and a spectrum is calculated based on transmitted light. In the ATR method, a prism having a high refractive index in an infrared region is used and a spectrum is calculated based on reflected light totally reflected on the sample surface.

As described above, the first resin 30 and the second resin 40 are different resins. The first resin 30 and the second resin 40 being different resins can also be checked by using Raman spectroscopy. Specifically, Raman scattered light of the first resin 30 and the second resin 40 is measured at each wave number by a microscopic Raman spectrometer (for example, LabRAM HR Evolution manufactured by Horiba, Ltd.), the horizontal axis is plotted as the wave number and the vertical axis is plotted as the scattering intensity, and Raman spectrums of the first resin 30 and the second resin 40 are acquired. Then, the Raman spectrum of the first resin 30 and the Raman spectrum of the second resin 40 are compared with a spectrum library. Accordingly, in the case where combinations of peak positions are different, it can be found that the first resin 30 and the second resin 40 are different resins.

Further, in the case where the first resin 30 contains a polyester, the Raman spectrum thereof preferably has a peak derived from an ester group at a position at a wave number of 1715 cm⁻¹ or more and 1735 cm⁻¹ or less and a peak derived from a benzene ring at a position at a wave number of 1600 cm⁻¹ or more and 1725 cm⁻¹ or less.

In the case where the first resin 30 contains a polycarbonate, the Raman spectrum thereof preferably has peaks derived from a carbonate group at a position at a wave number of 1760 cm⁻¹ or more and 1780 cm⁻¹ or less, a position at a wave number of 1225 cm⁻¹ or more and 1245 cm⁻¹ or less, and a position at a wave number of 880 cm⁻¹ or more and 900 cm⁻¹ or less, a peak derived from a benzene ring at a position at a wave number of 1600 cm⁻¹ or more and 1725 cm⁻¹ or less, and a peak derived from a methyl group at a position at a wave number of 2960 cm⁻¹ or more and 2970 cm⁻¹ or less.

In the case where the first resin 30 contains a an acrylic resin, the Raman spectrum thereof preferably has no peak derived from a methyl group at a position at a wave number of 2800 cm⁻¹ or more and 3000 cm⁻¹ or less, no peak derived from an ester group at a position at a wave number of 1715 cm⁻¹ or more and 1735 cm⁻¹ or less, no peak derived from a benzene ring, and no peak at a position at a wave number of 1800 cm⁻¹ or more and 2500 cm⁻¹ or less.

The Raman spectrum of the second resin 40 may have a plurality of peaks at the peak positions of the first resin 30, but the combination of the peak positions is preferably different from that of the first resin 30 when viewed in the entire spectrum. The combination of peaks can be determined by a known method or technique. For example, the Raman spectrum may be compared with the spectrum library, and the positions of the peaks characteristic of the disclosed functional groups and the peaks paired due to stretching and bending vibration may be specified. Note that, in the case where the Raman spectrum of the first resin 30 has a peak at a position (wave number) not included in the Raman spectrum of the second resin 40 or in the case where the Raman spectrum of the second resin 40 has a peak at a position (wave number) not included in the Raman spectrum of the first resin 30, it can be said that the combination of peak positions is different between the Raman spectrum of the first resin 30 and the Raman spectrum of the second resin 40.

Note that, the measurement conditions of the microscopic Raman spectroscopy are as follows: a sample surface is irradiated with a monochromatic laser of 532 nm or 785 nm, and Raman scattered light scattered to a wavelength different from that of the incident light by molecular vibration is passed through a spectroscope to calculate a spectrum.

A loss modulus G″ of the first resin 30 is preferably greater than the loss modulus G″ of the second resin 40. For example, a ratio of the loss modulus G″ of the second resin 40 to the loss modulus G″ of the first resin 30 (loss modulus G″ of second resin 40/loss modulus G″ of first resin 30) is preferably 20% or less, more preferably 15% or less, and still more preferably 10% or less. In the case where the ratio of the loss modulus G″ of the second resin 40 to the loss modulus G″ of the first resin 30 is within this range, the first resin 30 and the glass can be appropriately bonded to each other while appropriately preventing damage of the first resin 30 that is a bent portion.

A difference between the thickness D2 of the second resin 40 and the thickness D1 of the first resin 30 is preferably 100 μm or less, more preferably 80 μm or less, and still more preferably 60 μm or less. With such a small difference in thickness, a step between the first resin 30 and the second resin 40 can be reduced.

The width W2 of the second resin 40 is preferably smaller than the width W1 of the first resin 30. For example, a ratio of the width W2 of the second resin 40 to the width W1 of the first resin 30 (width W2/width W1) is preferably 0.006 or more and 0.2 or less, more preferably 0.008 or more and 0.18 or less, and still more preferably 0.1 or more and 0.16 or less. In the case where the ratio of the width W2 of the second resin 40 to the width W1 of the first resin 30 is within this range, the first resin 30 and the glass can be appropriately bonded to each other while appropriately preventing damage of the first resin 30 that is a bent portion.

### (Three-Point Bending Strength Test)

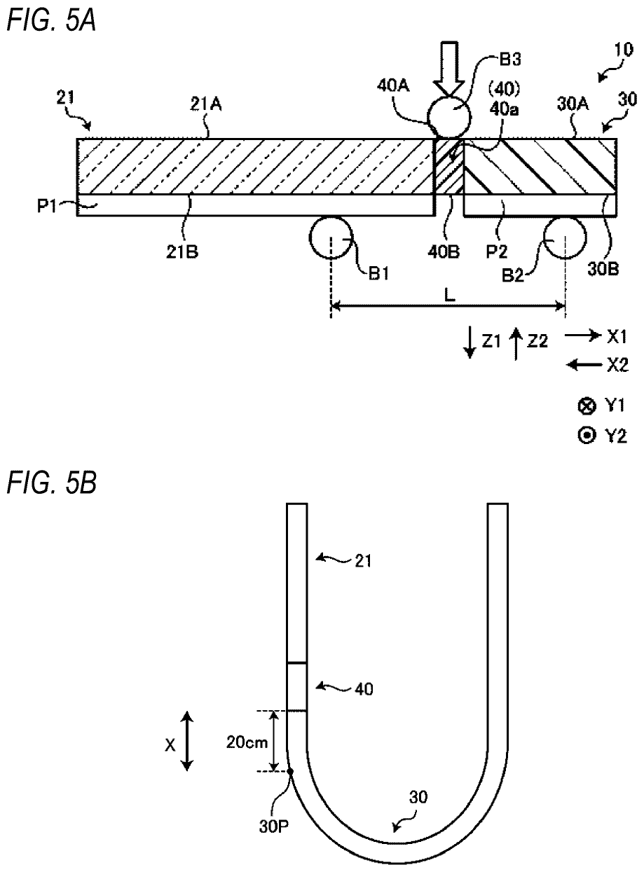

FIG. 5A is a schematic diagram illustrating test conditions in a three-point bending strength test. The cover member 10 formed as described above preferably has an average breaking load, which is obtained by measuring a breaking load ten times in a three-point bending strength test defined below, of 1.5 N or more. Further, the cover member 10 preferably has an average bending adhesive strength BS, which is calculated by using the equation described below, of 15 MPa or more, more preferably 25 MPa or more and 300 MPa or less, and still more preferably 45 MPa or more and 250 MPa or less. In the case where the average bending adhesive strength in the three-point bending strength test is within this range, it is seen that the first resin 30 and the first glass 21 are appropriately bonded to each other with the second resin 40, the durability when the second resin 40a receives a tensile force, the bending adhesive strength at an interface between the second resin 40a and the first resin 30, and the bending adhesive strength at an interface between the second resin 40a and the glass 21 can be comprehensively improved, and peeling-off can be prevented. In addition, in the three-point bending strength test, since the load is statically continuously increased and, in particular, the load at the interface becomes large, this is a method suitable for evaluating an adhesive force by inducing interfacial breakage of the second resin 40.

As illustrated in FIG. 5A, in the three-point bending strength test, the cover member 10 is disposed on plates P1 and P2 such that a main surface of the plate P1 on the direction Z2 side is in contact with the main surface 21B of the first glass 21, a main surface of the plate P2 on the direction Z2 side is in contact with the main surface 30B of the first resin 30, and the main surface 40B of the second resin 40a is in an open state. The plates P1 and P2 are plate-shaped members made of SUS having a thickness of 0.5 mm. Then, a columnar shaft portion B1 is disposed to be in contact with the main surface of the plate P1 on the direction Z1 side, and a columnar shaft portion B2 is disposed to be in contact with the main surface of the plate P2 on the direction Z1 side. More specifically, the shaft portions B1 and B2 are fixed such that a distance in the X direction from a center of the second resin 40a to a center of the shaft portion B1 is equal to a distance in the X direction from the center of the second resin 40a to a center of the shaft portion B2 and a distance L in the X direction from the center of the shaft portion B1 to the center of the shaft portion B2 is 30 mm when viewed from the Y direction. Note that, the shaft portions B1 and B2 are members made of stainless steel and have a diameter of 5 mm.

In this state, a load is applied while a shaft portion B3 having the same material and shape as the shaft portions B1 and B2 is in contact with the main surface 40A of the second resin 40a, and the load applied from the shaft portion B3 to the main surface 40A is increased under the condition of a test speed of 5 mm/min. Then, when the load when the cover member 10 is broken is defined as an average breaking load P, the average bending adhesive strength BS is expressed as BS=(3×P×L2)/(2×W2×D2²) using the breaking load P, the width W2 of the second resin 40, the thickness D2 of the second resin 40, and the distance L between the fulcrums (the distance between the shaft portions B1 and B2).

### (Bending Durability Test)

FIG. 5B is a schematic diagram illustrating test conditions in a bending durability test. In addition, it is preferable that there is no broken portion in the first resin 30 of the cover member 10 after a bending durability test defined below is performed. The absence of the broken portion can be checked by using an optical microscope (for example, LMS-4100 manufactured by Olympus Corporation or VHX-8000 manufactured by Keyence Corporation). It can be seen that the breakage of the first resin 30 due to the repeated bending can be prevented by the absence of the broken portion in the first resin 30.

The bending durability test is performed under the following measurement condition 1 or 2 by using, for example, a planar body no-load U-shaped stretching jig (for example, a planar body no-load U-shaped stretching tester DMLHB-FS-C manufactured by YUASA SYSTEM Co., Ltd.) using a desktop durability tester.

### (Measurement Condition 1)

In the cover member 10, a sample is cut out such that one end is the first glass 21 and the other end is the first resin 30. A total length of the sample is set to a short side length of 30 mm and a long side length of 300 mm, and a ratio of the lengths of the first glass 21 and the first resin 30 is set to 1:5. Note that, at this time, OCA may be attached to one surface. The second resin 40 adheres between the first glass 21 and the first resin 30 in a width range of 5 mm or less.

Next, the first glass 21 and the second resin 40 are fixed to the jig of the measurement device, and as illustrated in FIG. 5B, the first resin 30 is bent at a position 30P, which is 20 mm away from a bonding interface with the second resin 40 in the X direction. A curvature radius is R20 mm, a reciprocating speed is 80 rpm, and the bending is repeated 200,000 times.

### (Measurement Condition 2)

In the case of only observing the breaking durability of the first resin 30, the bending durability test may be performed by cutting only the first resin 30 into a short side length of 30 mm and a long side length of 300 mm and installing only the first resin 30 in the device.

In the cover member 10, an average change rate F in the visible light transmittance of the first resin 30 is preferably less than 1.5% before and after the bending durability test. In the case where the average change rate F of the first resin 30 is less than 1.5%, cloudiness of the first resin 30 due to the repeated bending can be prevented, and deterioration of the visibility can be prevented. The average change rate F in the visible light transmittance of the first resin 30 can be calculated according to the following equation (2).

$$F = \{ ( F 0 - F 1 ) / F 0 \} \times 100 \qquad ( 2 )$$

Here, F0 refers to an average value of external transmittances for light having wavelengths of 380 nm or more and 780 nm or less of the first resin 30 sampled at intervals of 2 nm before the bending durability test. In addition, F1 refers to an average value of the external transmittances for light having wavelengths of 380 nm or more and 780 nm or less of the first resin 30 after the bending durability test.

As described above, it is preferable that the cover member 10 has no broken portion in the first resin 30 after the bending durability test in which the bending is performed 200,000 times at a curvature radius of bending of 20 mm.

In addition, after the bending durability test in which the bending is performed 200,000 times at a curvature radius of bending of 20 mm, it is preferable, in the cover member 10, that the second resin 40 has no broken portion, and the bonded portion between the first resin 30 and the second resin 40 and the bonded portion between the first glass and the second resin 40 are not peeled off.

In addition, after the above bending durability test is performed, it is preferable, in the cover member 10, that the first resin 30 has no broken portion, and there is no peeling-off due to cohesive breakage of the second resin 40 at the bonded portion between the first resin 30 and the second resin 40 and the bonded portion between the first glass 21 and the second resin 40 or due to breakage at an interface in the bonded portion between the first resin 30 and the second resin 40 and the bonded portion between the first glass 21 and the second resin 40. It can be visually recognized that the first resin 30 has no broken portion. In addition, the absence of a cohesive breakage portion in the second resin 40 can be checked by using an optical microscope or a three-dimensional shape measuring machine. Similarly, it can be found by using an optical microscope or a three-dimensional shape measuring machine that the bonded portion between the first resin 30 and the second resin 40 and the bonded portion between the first glass 21 and the second resin 40 are not peeled off. It is seen that the breakage of the first resin and the peeling-off of the second resin 40 due to the repeated bending can be prevented by the absence of the broken portion in the first resin 30, the absence of the cohesive breakage portion in the second resin 40, and the absence of the interfacial breakage in the bonded portion with the second resin 40.

In addition, in the above description, the first resin is a thermoplastic resin or a thermoplastic elastomer, but is not limited to a thermoplastic resin or a thermoplastic elastomer as long as the first resin 30 is a material having no broken portion after the above bending durability test is performed. For example, the first resin may be a cured product of a curable resin. In this case, the first resin may be the same material as the second resin, or may be a cured product of a curable resin different from the second resin.

That is, the cover member may include: a first glass; a first resin; and a second resin provided between a side surface of the first glass and a first side surface of the first resin and configured to bond the first glass and the first resin, in which the first resin and the second resin may be a cured product of a curable resin, and the second resin may have a loss modulus G″ of 10⁶ Pa or more at normal temperature.

In addition, the cover member may include: a first glass; a first resin; and a second resin provided between a side surface of the first glass and a side surface of the first resin and configured to bond the first glass and the first resin, in which after a bending durability test in which bending is performed 200,000 times at a curvature radius of bending of 20 mm, the first resin and the second resin may have no broken portion, and a bonded portion between the first resin and the second resin and a bonded portion between the first glass and the second resin may not be peeled off.

### (Method for Producing Display Device)

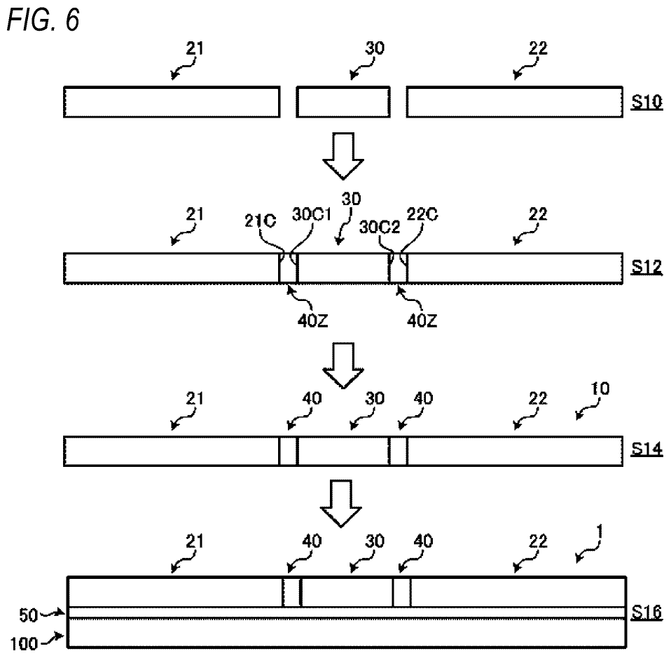

Next, a method for producing the display device 1 is described. FIG. 6 is a schematic diagram illustrating a method for producing a cover member according to the present embodiment. In the present production method, the first glass 21, the second glass 22, and the first resin 30 are prepared (step S10). Then, a curable resin 40Z, which is the uncured second resin 40, is applied between the side surface 21C of the first glass 21 and the side surface 30C1 of the first resin 30 to adhere the side surface 21C and the side surface 30C1 with the curable resin 40Z. Similarly, the curable resin 40Z is applied between the side surface 22C of the second glass 22 and the side surface 30C2 of the first resin 30 to adhere the side surface 22C and the side surface 30C2 with the curable resin 40Z (step S12). Thereafter, the curable resin 40Z is cured to form the second resin 40 between the side surface 21C of the first glass 21 and the side surface 30C1 of the first resin 30 and between the side surface 22C of the second glass 22 and the side surface 30C2 of the first resin 30, to thereby bond these by the second resin 40 (step S14). Accordingly, the cover member 10 is produced. Thereafter, the cover member 10 and the display panel 100 adhere to each other with the connection layer 50, to produce the display device 1 (step S16).

As described above, in the cover member 10 according to the present embodiment, the first glass 21 and the first resin 30 are bonded to each other with the second resin 40, and the second glass 22 and the first resin 30 are bonded to each other with the second resin 40. With the cover member 10 having such a structure, the first glass 21 and the first resin 30 can be appropriately bonded to each other with the second resin 40 while the cover member 10 is appropriately bent by the first resin 30.

### Other Examples

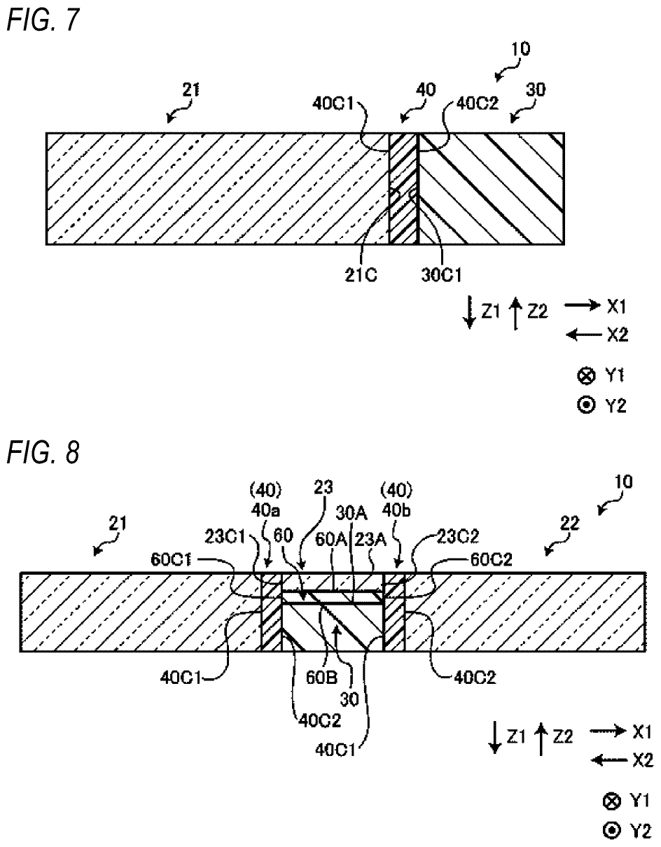

Other examples of the structure of the cover member 10 are described. FIGS. 7 to 12 are schematic diagrams illustrating other examples of the cover member.

### (Example Including No Second Glass)

As illustrated in FIG. 7, the cover member 10 may have a configuration including the first glass 21, the first resin 30, and the second resin 40, and including no second glass 22. In this case, the second resin 40 is provided between the first glass 21 and the first resin 30 in the X direction, and bonds the side surface 21C of the first glass 21 on the direction X1 side and the side surface 30C1 of the first resin 30 on the direction X2 side.

In the case where the second glass 22 is not provided as described above, preparation of the second glass 22 is unnecessary in producing the cover member 10. In this case, the first glass 21 and the first resin 30 are prepared, the curable resin 40Z is applied between the side surface 21C of the first glass 21 and the side surface 30C1 of the first resin 30, and the curable resin 40Z is cured to form the second resin 40 to bond the side surface 21C of the first glass 21 and the side surface 30C1 of the first resin 30 to each other with the second resin 40.

The present disclosure also relates to a method for producing a cover member, including: a step of applying a curable resin between a side surface of a first glass and a first side surface of a plate-shaped first resin, which is a thermoplastic resin or a thermoplastic elastomer; and a step of curing the curable resin to form a second resin having a loss modulus G″ of 10⁶ Pa or more at 35° C., thereby bonding the first glass and the first resin with the second resin.

Note that, the cover member 10 may have a configuration in which three or more glasses arranged in the X direction are bonded to one another with the first resin 30 and the second resin 40. In this case, for example, the second resin 40, the first resin 30, the second resin 40, and another first glass 21 may be further arranged in this order toward the direction X2 on the direction X2 side of the first glass 21 in the present embodiment illustrated in FIG. 3. That is, the glass (first glass 21), the second resin 40, the first resin 30, and the second resin 40 arranged in the X direction may be used as a constituent unit, and this constituent unit may be repeatedly disposed in the X direction.

### (Example Including Third Glass)

A third glass 23 may be disposed on the main surface 30A of the first resin 30. In this case, for example, as illustrated in FIG. 8, a third resin 60 and the third glass 23 are disposed on the main surface 30A of the first resin 30 in this order toward the direction Z2, and the main surface 23A of the third glass 23 on the direction Z2 side is exposed. Specifically, the third resin 60 is provided between the first resin 30 and the third glass 23 in the Z direction, and bonds the main surface 30A of the first resin 30 on the direction Z2 side and the main surface 23B of the third glass 23 on the direction Z1 side. That is, in the third resin 60, a main surface 60B in the direction Z1 is bonded to the main surface 30A of the first resin 30, and a main surface 60A in the direction Z2 is bonded to the main surface 23B of the third glass 23.

That is, the cover member according to the present disclosure may further include a third glass provided on a main surface of the first resin, and a third resin provided between the third glass and the first resin and configured to bond the third glass and the first resin.

In this manner, by providing the third glass 23 on the first resin 30, the main surface of the cover member 10 on the exposed side can be covered with a glass. Therefore, an appearance of the display device 1 can be improved, and for example, a touch property in the case of using the display device 1 as a touch panel can be improved. Therefore, the configuration in which the third glass 23 is provided on the first resin 30 is particularly preferred. Note that, even in the configuration in which the second glass 22 is not provided as illustrated in FIG. 7, the third glass 23 may be provided on the first resin 30 as illustrated in FIG. 8.

The thickness (a length from the main surface 23A to the main surface 23B in the Z direction) of the third glass 23 is preferably smaller than the thickness D1 of the first glass 21. The thickness of the third glass 23 is preferably 6% or more and 50% or less, more preferably 8% or more and 45% or less, and still more preferably 10% or more and 40% or less with respect to the thickness D1 of the first glass 21. In the case where the thickness of the third glass 23 is thus small, the third glass 23 can be bent appropriately.

Note that, since the properties of the third glass 23, excluding the thickness, are the same as the properties of the first glass 21 described above, the description thereof is omitted.

The third resin 60 may be any resin that can bond the third glass 23 and the first resin 30 and that can be bent. For example, the third resin 60 may be OCR or OCA similar to the connection layer 50, or may be the same material as the second resin 40. Note that, in the case where the third resin 60 is the same material as the second resin 40, there may be no interface between the second resin 40 and the third resin 60, and the second resin 40 and the third resin 60 may be integrated to each other. The same applies to the following.

Further, in the example in FIG. 8, the third glass 23 and the third resin 60 are provided between the second resin 40a and the second resin 40b in the X direction. That is, in the third glass 23, the side surface 23C1 on the direction X2 side is bonded to the side surface 40C2 of the second resin 40a, and the side surface 23C2 on the direction X1 side is bonded to the side surface 40C1 of the second resin 40b. Similarly, in the third resin 60, a side surface 60C1 on the direction X2 side is bonded to the side surface 40C2 of the second resin 40a, and a side surface 60C2 on the direction X1 side is bonded to the side surface 40C1 of the second resin 40b.

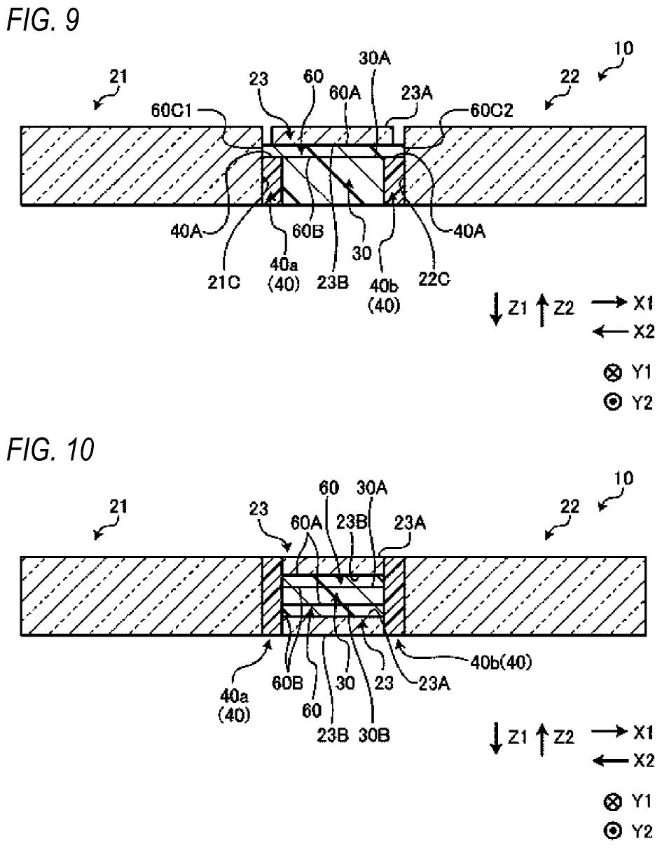

In addition, as illustrated in an example in FIG. 9, the third glass 23 and the third resin 60 may be provided on the second resin 40 on the direction Z2 side. In this case, the third resin 60 is provided over the main surface 30A of the first resin 30 and the main surfaces 40A of the second resins 40a and 40b, and the third glass 23 is provided on the main surface 60A of the third resin 60. In this case, the third glass 23 is preferably separated from the first glass 21 and the second glass 22 in the X direction. That is, it is preferable that the side surface 21C of the first glass 21 on the direction X1 side is separated from the side surface 23C1 of the third glass 23, and the side surface 22C of the second glass 22 on the direction X2 side is separated from the side surface 23C2 of the third glass 23.

In addition, as illustrated in an example in FIG. 10, the third glass 23 may be provided on the first resin 30 on both the direction Z2 side and the direction Z1 side. In this case, for example, the third resin 60 and the third glass 23 are disposed in this order toward the direction Z1 on the main surface 30B side of the first resin 30. Specifically, the third resin 60 on the first resin 30 on the direction Z1 side bonds the main surface 30B of the first resin 30 on the direction Z1 side and the main surface 23A of the third glass 23 on the direction Z2 side. That is, in the third resin 60, the main surface 60A in the direction Z2 is bonded to the main surface 30B of the first resin 30, and the main surface 60B in the direction Z1 is bonded to the main surface 23A of the third glass 23. In the case where the third glass 23 is provided on both main surfaces of the first resin 30 in this manner, the volume occupied by the first resin 30 can be reduced while maintaining flexibility, optical properties, such as the transmittance and the refractive index, of the display device 1 are closer to those of the first resin 30 to improve the appearance, and rigidity can be increased by the third glass 23 to suitably improve the touch property.

That is, in the cover member according to the present disclosure, the third glass and the third resin are preferably provided on one main surface and the other main surface of the first resin.

Note that, in the example in FIG. 10, the third resin 60 and the third glass 23 on the direction Z1 side are provided between the second resin 40a and the second resin 40b in the X direction, similar to FIG. 8. However, the present disclosure is not limited thereto, and the third resin 60 and the third glass 23 on the direction Z1 side may be provided on the second resin 40 on the direction Z1 side, similar to FIG. 9.

### (Example of Providing First Resin and Second Resin in Recessed Portion of First Glass)

The cover member according to the present disclosure may be a cover member for a display, including: a first glass having a recessed portion in a part of a main surface; a first resin provided in the recessed portion, which is a thermoplastic resin or a thermoplastic elastomer; a second resin provided in the recessed portion between a side surface of the recessed portion and a first side surface of the first resin and configured to bond the first glass and the first resin; and a third resin provided between a bottom surface of the recessed portion and a main surface of the first resin and configured to bond the bottom surface of the recessed portion and the main surface of the first resin, in which the second resin is a resin different from the first resin and has a loss modulus G″ of 10⁶ Pa or more at 35° C.

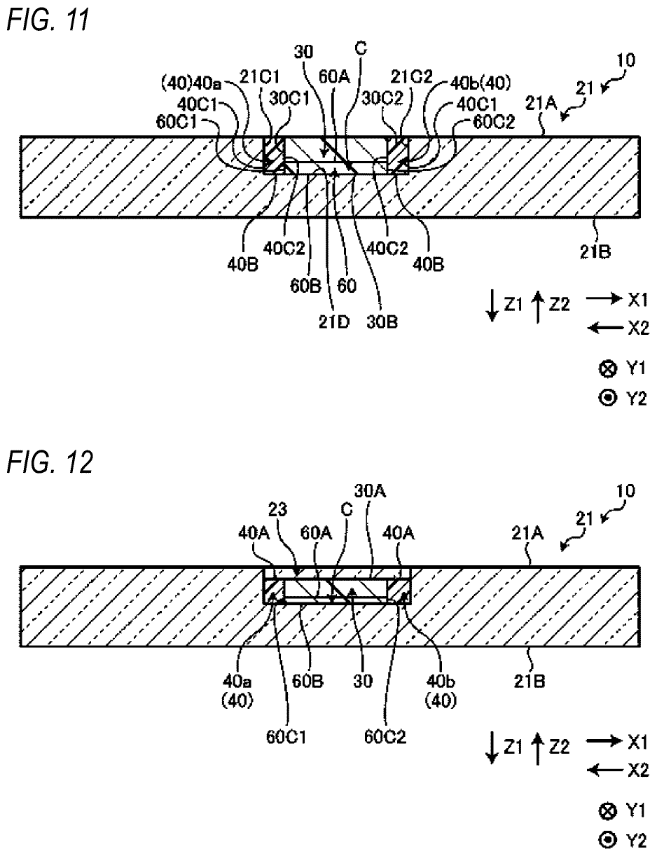

In the above example, a recessed portion C may be formed in the main surface of the first glass 21, and the first resin 30 and the second resin 40 may be disposed in the recessed portion C. Specifically, in the present example, as illustrated in FIG. 11, the recessed portion C is formed in a part of the entire main surface 21A of the first glass 21. It can be said that the recessed portion C is a recess recessed from the main surface 21A toward the direction Z1 side. The recessed portion C is formed from an end portion on the direction Y1 side to an end portion on the direction Y2 side of the first glass 21. The recessed portion C has a bottom surface 21D that is a surface on the direction Z1 side, a side surface 21C1 that is a surface on the direction X2 side, and a side surface 21C2 that is a surface on the direction X1 side.

The first resin 30, the second resin 40, and the third resin 60 are provided in the recessed portion C. Specifically, as illustrated in FIG. 11, the third resin 60 and the first resin 30 are disposed on the bottom surface 21D in this order toward the direction Z2. The third resin 60 is provided between the bottom surface 21D and the first resin 30 in the Z direction, and bonds the bottom surface 21D and the main surface 30B of the first resin 30 on the direction Z1 side. That is, in the third resin 60, the main surface 60B in the direction Z1 is bonded to the bottom surface 21D, and the main surface 60A in the direction Z2 is bonded to the main surface 30B of the first resin 30. In addition, the first resin 30 and the third resin 60 are provided between the second resin 40a and the second resin 40b in the X direction. That is, in the second resin 40a, the side surface 40C1 is bonded to the side surface 21C1 of the recessed portion C, the side surface 40C2 is bonded to the side surface 30C1 of the first resin 30 and the side surface 60C1 of the third resin 60, and the main surface 40B is bonded to the bottom surface 21D. Similarly, in the second resin 40b, the side surface 40C1 is bonded to the side surface 21C2 of the recessed portion C, the side surface 40C2 is bonded to the side surface 30C2 of the first resin 30 and the side surface 60C2 of the third resin 60, and the main surface 40B is bonded to the bottom surface 21D. Note that, in the example in FIG. 11, the first resin 30 and the third resin 60 are provided between the second resin 40a and the second resin 40b in the X direction, but are not limited thereto, and may be provided on the second resin 40 on the direction Z1 side.

In the present example, the first glass 21 has a small thickness at a region where the recessed portion C is formed, and a portion where the recessed portion C is formed can be bent together with the first resin 30. In the present example, by filling the recessed portion C with the first resin 30, the second resin 40, or the like, the first glass 21 can be appropriately bent while reinforcing the portion where the recessed portion C is formed.

In addition, as illustrated in FIG. 12, the third glass 23 may be provided on the first resin 30 provided in the recessed portion C. In this case, the third glass 23 is provided on the main surface 30A of the first resin 30 and the main surfaces 40A of the second resins 40a and 40b, and is bonded to the main surfaces 40A of the second resins 40a and 40b. Note that, the third resin 60 may also be provided between the third glass 23 and the first resin 30 in the Z direction.

### (Effects)

As described above, the cover member 10 according to a first aspect of the present disclosure is a cover member of a display, and includes: the first glass 21; the first resin 30 that is a thermoplastic resin or a thermoplastic elastomer; and the second resin 40 provided between the side surface 21C of the first glass 21 and the side surface 30C1 (first side surface) of the first resin 30 and configured to bond the first glass 21 and the first resin 30. The second resin 40 is a resin different from the first resin 30 and has a loss modulus G″ of 10⁶ Pa or more at normal temperature (35° C.). According to the present disclosure, the first glass 21 and the first resin 30 can be appropriately bonded to each other with the second resin 40 while the cover member 10 is appropriately bent by the first resin 30. Further, by forming the first resin 30 with such a member, a step of filling with an uncured resin and a step of curing the filled resin are unnecessary for the first resin 30, and the production process can be simplified. In addition, by forming the second resin 40 with such a member, the first resin 30 and the first glass 21 can be appropriately bonded to each other, and breakage and peeling-off of the bonded portion due to bending can be prevented.

The cover member 10 according to a second aspect of the present disclosure is the cover member 10 according to the first aspect, in which the second resin 40 is preferably a cured resin of a curable resin. The first resin 30 and the first glass 21 can be appropriately bonded to each other, and breakage and peeling-off of the bonded portion due to bending can be prevented.

The cover member 10 according to a third aspect of the present disclosure is the cover member 10 according to the first aspect or the second aspect, in which the first resin 30 preferably has a glass transition temperature Tg of 60° C. or higher and 200° C. or lower, and the second resin 40 preferably has a glass transition temperature Tg of −100° C. or higher and lower than 60° C. Breaking and peeling-off of the bonded portion can be prevented while simplifying the production process.

The cover member 10 according to a fourth aspect of the present disclosure is the cover member 10 according to any one of the first aspect to the third aspect, in which the first resin 30 preferably contains, as a main component, at least one or more selected from a polyester, an acrylic resin, a polyethylene, and a polycarbonate. Damage and cloudiness of the bent portion due to repeated bending can be prevented.

The cover member 10 according to a fifth aspect of the present disclosure is the cover member 10 according to any one of the first aspect to the fourth aspect, in which the second resin 40 preferably contains, as a main component, at least one or more selected from a cured acrylic resin and a cured epoxy resin. The first resin 30 and the first glass 21 can be appropriately bonded to each other, and breakage and peeling-off of the bonded portion due to bending can be prevented.

The cover member 10 according to the present aspect is the cover member 10 according to any one of the first aspect to the fifth aspect, in which an infrared light transmittance waveform of the first resin 30 measured by FT-IR and an infrared light transmittance waveform of the second resin 40 measured by FT-IR preferably have different combinations of peak positions. Breaking and peeling-off of the bonded portion due to bending can be prevented.

The cover member 10 according to a sixth aspect of the present disclosure is the cover member 10 according to any one of the first aspect to the fifth aspect, in which a breaking load is preferably 1.5 N or more in a three-point bending strength test. The strength of the second resin 40 is sufficient, and breakage and peeling-off of the bonded portion can be appropriately prevented.

The cover member 10 according to a seventh aspect of the present disclosure is the cover member 10 according to any one of the first aspect to the sixth aspect, in which the first resin 30 preferably has no broken portion after a bending durability test in which bending is performed 200,000 times at a curvature radius of bending of 20 mm. Damage of the bent portion due to repeated bending can be prevented.

The cover member 10 according to an eighth aspect of the present disclosure is the cover member 10 according to the seventh aspect, in which an average change rate in a visible light transmittance of the first resin 30 before and after the bending durability test is preferably less than 1.5%. It can be seen that cloudiness of the first resin 30 due to repeated bending can be prevented, and deterioration of visibility can be prevented.

The cover member 10 according to a ninth aspect of the present disclosure is the cover member 10 according to any one of the first aspect to the eighth aspect, in which after a bending durability test in which bending is performed 200,000 times at a curvature radius of bending of 20 mm, it is preferable that the second resin 40 has no broken portion and a bonded portion between the first resin 30 and the second resin 40 and a bonded portion between the first glass 21 and the second resin 40 are not peeled off. Accordingly, peeling-off of the bonded portion due to bending can be prevented.

The cover member 10 according to a tenth aspect of the present disclosure includes: the first glass 21; the first resin 30; and the second resin 40 provided between the side surface 21C of the first glass 21 and the side surface 30C1 (first side surface) of the first resin 30 and configured to bond the first glass 21 and the first resin 30. In the cover member 10, after a bending durability test in which bending is performed 200,000 times at a curvature radius of bending of 20 mm, the first resin 30 and the second resin 40 have no broken portion, and a bonded portion between the first resin 30 and the second resin 40 and a bonded portion between the first glass 21 and the second resin 40 are not peeled off. The cover member 10 according to the present disclosure can prevent peeling-off at the bonded portion due to bending, and can prevent breakage of the first resin 30 and the second resin 40 due to repeated bending.

The cover member 10 according to an eleventh aspect of the present disclosure is the cover member 10 according to any one of the first aspect to the tenth aspect, in which the second resin 40 preferably has a width W2 of 10 μm or more and 3,000 μm or less. It is possible to prevent the size of the bonded portion from being excessively large while appropriately bonding the first resin 30 or the glass.

The cover member 10 according to a twelfth aspect of the present disclosure is the cover member 10 according to any one of the first aspect to the eleventh aspect, in which the first resin 30 preferably has a width W1 of 2 cm or more. The bent portion can be sufficiently enlarged, and the cover member 10 can be appropriately bent.

The cover member 10 according to a thirteenth aspect of the present disclosure is the cover member 10 according to any one of the first aspect to the twelfth aspect, in which a difference between the thickness D1 of the first resin 30 and the thickness D0 of the first glass 21 is preferably 100 μm or less. Accordingly, a step between the first resin 30 and the first glass 21 can be reduced.

The cover member 10 according to a fourteenth aspect of the present disclosure is the cover member 10 according to any one of the first aspect to the thirteenth aspect, in which the first glass 21 preferably has a thickness D0 of 0.7 mm or more. Accordingly, it is possible to prevent a decrease in bondability with the second resin 40 due to the first glass 21 being too thin.

The cover member 10 according to a fifteenth aspect of the present disclosure is the cover member 10 according to any one of the first aspect to the fourteenth aspect, and preferably further includes the second glass 22, in which the second resin 40 is also provided between the side surface 30C2 (second side surface) of the first resin 30 and the side surface 22C of the second glass 22 to bond the first resin 30 and the second glass 22. Accordingly, it is possible to appropriately bend the first resin 30 between the first glass 21 and the second glass 22 as a starting point while preventing peeling-off at the bonded portion between the second glass 22 and the second resin 40.

The cover member 10 according to a sixteenth aspect of the present disclosure is the cover member 10 according to the fifteenth aspect, and preferably further includes the third glass 23 provided on the main surface 30A of the first resin 30, and the third resin 60 provided between the third glass 23 and the first resin 30 and configured to bond the third glass 23 and the first resin 30. In the case where the third glass 23 is provided on the main surface 30A, the appearance of the display device 1 can be improved, and for example, the touch property in the case of using the display device 1 as a touch panel can be improved.

The cover member 10 according to a seventeenth aspect of the present disclosure is the cover member 10 according to the sixteenth aspect, in which the third glass 23 and the third resin 60 are preferably provided on one main surface 30A and the other main surface 30B of the first resin 30. In the case where the third glass 23 is provided on both surfaces of the first resin 30, the volume occupied by the first resin 30 can be reduced while maintaining the flexibility, and the appearance and the touch property of the display device 1 can be suitably improved.

The cover member 10 according to an eighteenth aspect of the present disclosure is the cover member 10 according to any one of the first aspect to the seventeenth aspect, in which the first resin 30 and the second resin 40 are preferably transparent to visible light. Accordingly, visible light can also be transmitted from the first resin 30 and the second resin 40, and the visibility of the image can be improved.

The cover member 10 according to a nineteenth aspect of the present disclosure is the cover member 10 according to the eighteenth aspect, in which a refractive index of the second resin 40 is preferably a value between a refractive index of the first glass 21 and a refractive index of the first resin 30. Accordingly, the refractive index continuously changes, and the bonded portion can be less likely to be visually recognized.

The cover member 10 according to a twentieth aspect of the present disclosure is a cover member for a display, including: the first glass 21 having the recessed portion C in a part of the main surface 23A; the first resin 30 that is a thermoplastic resin or a thermoplastic elastomer and provided in the recessed portion C; the second resin 40 provided in the recessed portion C between the side surface 21C1 of the recessed portion C and the first side surface of the first resin 30 and configured to bond the first glass 21 and the first resin 30; and the third resin 60 provided between the bottom surface 21D of the recessed portion C and the main surface 30B of the first resin 30 and configured to bond the bottom surface 21D of the recessed portion C and the main surface 30B of the first resin 30, in which the second resin 40 is a resin different from the first resin 30 and has a loss modulus G″ of 10⁶ Pa or more at 35° C. According to the present disclosure, by filling the recessed portion C with the first resin 30, the second resin 40, or the like, the first glass 21 can be appropriately bent while reinforcing the portion where the recessed portion C is formed.

A method for producing the cover member 10 according to a twenty-first aspect of the present disclosure includes: a step of applying the curable resin 40Z between the side surface 21C of the first glass 21 and the side surface 30C1 of the plate-shaped first resin 30 that is a thermoplastic resin or a thermoplastic elastomer; and a step of curing the curable resin 40Z to form the second resin 40 having a loss modulus G″ of 10⁶ Pa or more at normal temperature (35° C.), thereby bonding the first glass 21 and the first resin 30 with the second resin 40. According to the present production method, it is possible to produce the cover member 10 capable of preventing peeling-off at the bonded portion.

### EXAMPLES

Next, Examples are described. Table 1 is a table showing the configuration and evaluation results of cover glasses in Examples.

TABLE 1

| | | Ex. 1 | Ex. 2 | Ex. 3 | Ex. 4 | Ex. 5 | Ex. 6 | Ex. 7 |
|---|---|---|---|---|---|---|---|---|
| Cond. | First glass | 30 mm × 30 mm × 1.5 mm | | | | | | |
| | First resin | No | PVC | PS | PET | PET | PET | PET |
| | Second resin | 107UV | No | No | 107UV | 65UV | 68UV | 81UV |
| | Loss modulus [Pa] | 2.16E+04 | No | No | 2.16E+04 | 6.44E+04 | 6.93E+06 | 7.69E+07 |
| | of second resin | | | | | | | |
| | Tg [° C.] of | −14.9 | No | No | −14.9 | −10.8 | 8.3 | 7.4 |
| | second resin | | | | | | | |
| | Adhesive | 21.0 | — | — | 11.3 | 11.9 | 33.1 | 55.6 |
| | strength BS [MPa] | | | | | | | |
| | Difference [nd] | | | | | | 0.145 | 0.145 |
| | in refractive | | | | | | | |
| | index between | | | | | | | |
| | first resin and | | | | | | | |
| | first glass | | | | | | | |
| Eval. | Bending | Peeled | Peeled | Peeled | Peeled | Peeled | Not | Not |
| | durability test: | off | off | off | off | off | peeled | peeled |
| | peeling-off at | | | | | | off | off |
| | bonded portion | | | | | | | |
| | Bending | Broken | — | — | Broken | Broken | Not | Not |
| | durability test: | | | | | | broken | broken |
| | breakage of | | | | | | | |
| | second resin | | | | | | | |
| | Bending | | Broken | Broken | Not | Not | Not | Not |
| | durability test: | | | | broken | broken | broken | broken |
| | breakage of | | | | | | | |
| | first resin | | | | | | | |
| | Bending | 10.2 | 10.2 | 1.52 | 0.66 | 0.66 | 0.66 | 0.66 |
| | durability test: | | | | | | | |
| | amount of change | | | | | | | |
| | in transmittance | | | | | | | |
| | (%) of first resin | | | | | | | |
| | Production | B | A | A | A | A | A | A |
| | easiness | | | | | | | |

| | | Ex. 8 | Ex. 9 | Ex. 10 | Ex. 11 | Ex. 12 | Ex. 13 |
|---|---|---|---|---|---|---|---|
| Condition | First glass | 30 mm × 30 mm × 1.5 mm | | | | | |
| | First resin | PE | PE | PMMA | PMMA | PC | PC |
| | Second resin | 65UV | 81UV | 65UV | 81UV | 65UV | 81UV |
| | Loss modulus [Pa] | 6.93E+06 | 7.69E+07 | 6.93E+06 | 7.69E+07 | 6.93E+06 | 7.69E+07 |
| | of second resin | | | | | | |
| | Tg [° C.] of | −10.8 | 7.4 | −10.8 | 7.4 | −10.8 | 7.4 |
| | second resin | | | | | | |
| | Adhesive | ND | ND | ND | ND | ND | ND |
| | strength BS [MPa] | | | | | | |
| | Difference [nd] | | | 0.01 | 0.01 | 0.076 | 0.076 |
| | in refractive | | | | | | |
| | index between | | | | | | |
| | first resin and | | | | | | |
| | first glass | | | | | | |
| Evaluation | Bending | Not | Not | Not | Not | Not | Not |
| | durability test: | peeled | peeled | peeled | peeled | peeled | peeled |
| | peeling-off at | off | off | off | off | off | off |
| | bonded portion | | | | | | |
| | Bending | Not | Not | Not | Not | Not | Not |
| | durability test: | broken | broken | broken | broken | broken | broken |
| | breakage of | | | | | | |
| | second resin | | | | | | |
| | Bending | Not | Not | Not | Not | Not | Not |
| | durability test: | broken | broken | broken | broken | broken | broken |
| | breakage of | | | | | | |
| | first resin | | | | | | |
| | Bending | 2.67 | 2.67 | 1.13 | 1.13 | 0.27 | 0.27 |
| | durability test: | | | | | | |
| | amount of change | | | | | | |
| | in transmittance | | | | | | |
| | (%) of first resin | | | | | | |
| | Production | A | A | A | A | A | A |
| | easiness | | | | | | |

### Example 1

In Example 1, a first glass having a vertical length of 30 mm, a horizontal length of 30 mm, and a thickness of 1.5 mm was prepared. Dragontrail manufactured by AGC Inc. was used as the first glass. Then, the first resin was not provided, and 107UV manufactured by Norland, which was an acrylic UV curable resin, was used as the second resin. The width W2 was 1 mm and the thickness D2 was 1.5 mm for the second resin. The second resin was bonded to the side surface of the first glass to obtain a cover member.

In Example 1, the loss modulus G″ of the second resin and the average breaking load in the three-point bending strength test of the cover member (second resin) were measured by the methods described in the present embodiment, and the average adhesive strength BS was calculated. Note that, the distance L between fulcrums in the three-point bending strength test was 30 mm. The results are shown in Table 1.

The refractive index n_{d} of the first resin and the refractive index n_{d} of the first glass were measured by the method described in the present embodiment. The difference between the refractive index n_{d} of the first resin and the refractive index n_{d} of the first glass (refractive index n_{d} of the first resin−refractive index n_{d} of the first glass) is shown in Table 1.

### Example 2

In Example 2, a cover member was produced in the same manner as in Example 1 except that polyvinyl chloride PVC (manufactured by Hikari Co., ltd.) was used as the first resin, the second resin was not provided, and the first resin and the first glass were directly bonded to each other. Note that, since the second resin was not provided in Example 2, the loss modulus G″ of the second resin and the average breaking load in the three-point bending strength test were not measured.

### Example 3

In Example 3, a cover member was produced in the same manner as in Example 1 except that a polystyrene PS (manufactured by Hikari Co., ltd.) was used as the first resin, the second resin was not provided, and the first resin and the first glass were directly bonded to each other. Since the second resin was not provided in Example 3, the loss modulus G″ of the second resin and the average breaking load in the three-point bending strength test were not measured.

### Example 4

In Example 4, a cover member was obtained by bonding the side surface of the first glass and the side surface of the first resin with the second resin by using PET (manufactured by Hikari Co., ltd.) as the first resin and 107UV manufactured by Norland, which was a UV curable resin, as the second resin. Note that, the dimensions of the glass and the second resin were the same as those in Example 1, the dimension of the first resin was the same as that of the glass in Example 1, and the distance L between fulcrums in the three-point bending strength test was 30 mm.

In Example 4, the loss modulus G″ of the second resin and the breaking load in the three-point bending strength test of the cover member (second resin) were measured by the methods described in the present embodiment. The measurement results are shown in Table 1.

### Example 5 to Example 13

In Example 5 to Example 13, cover members were obtained in the same manner as in Example 4 except that the materials of the first resin and the second resin were as shown in Table 1. Note that, PE is a polyethylene manufactured by AS ONE Corporation, PMMA is polymethyl methacrylate manufactured by Hikari Co., ltd., PC is a polycarbonate manufactured by Hikari Co., ltd., and 65UV, 68UV, and 81UV are UV curable resins manufactured by Norland.

### (Evaluation)

In the evaluation, according to the method described in the present embodiment, a bending durability test in which bending was performed 200,000 times at a curvature radius of bending of 20 mm was performed, and it was checked whether peeling-off (interfacial breakage) occurred at the bonded portion between the second resin (the first resin in Example 1) and the first glass after the bending durability test. By using an optical microscope LEXT OLS4100 manufactured by Olympus Corporation, a three-dimensional shape of the bonded portion with the first glass was measured, and a case where a region reduced to 5% or less of the thickness of the sample was present was evaluated as peeling-off (interfacial breakage), and a case where the region was not present was evaluated as no peeling-off (interfacial breakage).

As can be seen from Table 1, in Example 1 to Example 3 which are Comparative Examples in which only the first resin or only the second resin is provided, and in Example 4 and Example 5 which are Comparative Examples in which the loss modulus G″ of the second resin is less than 10⁶ Pa, the peeling-off occurs at the bonded portion. On the other hand, it can be seen that, in Example 6 to Example 13 which are Inventive Examples in which the first resin and the second resin are provided and the loss modulus G″ of the second resin is 10⁶ Pa or more, the peeling-off does not occur at the bonded portion.

As optional evaluation, the breakage of the second resin, the breakage of the first resin, and the amount of change in transmittance of the first resin after the bending durability test were evaluated. In the determination of the breakage of the first and second resins, a case where the resin was visually divided was determined as breakage, and a case where the resin was not visually divided was determined as no breakage. The amount of change in transmittance was calculated by the method described in the present embodiment.

In addition, as optional evaluation, production easiness was evaluated. In Example 1, since bonding was performed by using only the UV curable resin, the load of the coating step and the curing step was high, and thus B was given. In Example 2 to Example 13, since a thermoplastic resin was also used, the load of the coating step and the curing step was low, and thus A was given.

Although the embodiments of the present invention have been described above, the embodiments are not limited to the contents of these embodiments. In addition, the components described above should include those that can be easily conceived by a person skilled in the art, those that are substantially the same, and those within a so-called equivalent range. Further, the above components can be appropriately combined. Further, various omissions, substitutions, or modifications of the components can be made without departing from the gist of the embodiments described above.

### INDUSTRIAL APPLICABILITY

According to the present invention, it is possible to provide a cover member and a method for producing a cover member capable of preventing breakage and peeling-off of a bonded portion due to bending.

Although the present invention has been described in detail with reference to specific embodiments, it is apparent to those skilled in the art that various changes and modifications can be made without departing from the spirit and scope of the present invention.

The present application is based on a Japanese Patent Application (Japanese Patent Application No. 2022-210630) filed on Dec. 27, 2022, the contents of which are incorporated herein by reference.

### REFERENCE SIGNS LIST

1: display device
10: cover member
21: first glass
22: second glass
23: third glass
30: first resin
40: second resin
50: connection layer
60: third resin
100: display panel
110: panel connection layer
B1, B2, B3: shaft portion
P1, P2: plate
C: recessed portion

What is claimed is:

1. A cover member for a display, the cover member comprising:
a first glass;
a first resin that is a thermoplastic resin or a thermoplastic elastomer; and
a second resin that is provided between a side surface of the first glass and a first side surface of the first resin and configured to bond the first glass and the first resin, wherein
the second resin is a resin different from the first resin and has a loss modulus G″ of 10⁶ Pa or more at 35° C.

2. The cover member according to claim 1, wherein the second resin is a cured resin of a curable resin.

3. The cover member according to claim 1, wherein the first resin has a glass transition temperature Tg of 60° C. or higher and 200° C. or lower, and the second resin has a glass transition temperature Tg of −100° C. or higher and lower than 60° C.

4. The cover member according to claim 1, wherein the first resin comprises, as a main component, at least one or more selected from a polyester, an acrylic resin, a polyethylene, and a polycarbonate.

5. The cover member according to claim 1, wherein the second resin comprises, as a main component, at least one or more selected from a cured acrylic resin and a cured epoxy resin.

6. The cover member according to claim 1, having an average bending adhesive strength of 15 MPa or more in a three-point bending strength test.

7. The cover member according to claim 1, wherein the first resin has no broken portion after a bending durability test in which bending is performed 200,000 times at a curvature radius of bending of 20 mm.

8. The cover member according to claim 7, wherein the first resin has an average change rate in a visible light transmittance of less than 1.5% before and after the bending durability test.

9. The cover member according to claim 1, wherein
after a bending durability test in which bending is performed 200,000 times at a curvature radius of bending of 20 mm,
the second resin has no broken portion, and
a bonded portion between the first resin and the second resin and a bonded portion between the first glass and the second resin are not peeled off.

10. A cover member comprising:
a first glass;
a first resin; and
a second resin that is provided between a side surface of the first glass and a side surface of the first resin and configured to bond the first glass and the first resin, wherein
after a bending durability test in which bending is performed 200,000 times at a curvature radius of bending of 20 mm,
the first resin and the second resin have no broken portion, and
a bonded portion between the first resin and the second resin and a bonded portion between the first glass and the second resin are not peeled off.

11. The cover member according to claim 1, wherein the second resin has a width of 10 μm or more and 3,000 μm or less.

12. The cover member according to claim 1, wherein the first resin has a width of 2.0 cm or more.

13. The cover member according to claim 1, wherein a difference between a thickness of the first resin and a thickness of the first glass is 100 μm or less.

14. The cover member according to claim 1, wherein the first glass has a thickness of 0.7 mm or more.

15. The cover member according to claim 1, further comprising:
a second glass, wherein
the second resin is also provided between a second side surface of the first resin and a side surface of the second glass to bond the first resin and the second glass.

16. The cover member according to claim 15, further comprising:
a third glass that is provided on a main surface of the first resin; and
a third resin that is provided between the third glass and the first resin and configured to bond the third glass and the first resin.

17. The cover member according to claim 16, wherein the third glass and the third resin are provided on one main surface and the other main surface of the first resin.

18. The cover member according to claim 1, wherein the first resin and the second resin are transparent to visible light.

19. The cover member according to claim 18, wherein a refractive index of the second resin is a value between a refractive index of the first glass and a refractive index of the first resin.

20. A cover member for a display, the cover member comprising:
a first glass having a recessed portion in a part of a main surface;
a first resin that is a thermoplastic resin or a thermoplastic elastomer and provided in the recessed portion;
a second resin that is provided in the recessed portion between a side surface of the recessed portion and a first side surface of the first resin and configured to bond the first glass and the first resin; and
a third resin that is provided between a bottom surface of the recessed portion and a main surface of the first resin and configured to bond the bottom surface of the recessed portion and the main surface of the first resin, wherein
the second resin is a resin different from the first resin and has a loss modulus G″ of 10⁶ Pa or more at 35° C.

21. A method for producing a cover member, comprising:
a step of applying a curable resin between a side surface of a first glass and a first side surface of a plate-shaped first resin that is a thermoplastic resin or a thermoplastic elastomer; and
a step of curing the curable resin to form a second resin having a loss modulus G″ of 10⁶ Pa or more at 35° C., thereby bonding the first glass and the first resin with the second resin.
